(19) United States
(12) Patent Application Publication
(10) Pub. No.: US 2024/0092702 A1
(43) Pub. Date: Mar. 21, 2024

(54) METHOD AND SYSTEM FOR FABRICATING TWO-DIMENSIONAL MATERIAL BY USING GAS-PHASE METHOD

(71) Applicant: BEIHANG UNIVERSITY, Beijing (CN)

(72) Inventors: Shubin Yang, Beijing (CN); Zhiguo Du, Beijing (CN)

(21) Appl. No.: 18/039,474

(22) PCT Filed: Nov. 25, 2021
(86) PCT No.: PCT/CN2021/133055

§ 371 Date: May 30, 2023

(30) Foreign Application Priority Data
Dec. 14, 2020 (CN) 202011466046.4

(51) Int. Cl. C04B 41/53; H01J 37/32

(52) U.S. Cl. CPC C04B 41/5346; H01J 37/3244; H01J 2237/3341

(57) ABSTRACT

Provided are a method and system for preparing a two-dimensional material by means of a gas-phase method. The method comprises a gas-phase etching step: reacting gas having an etching effect with an MAX phase material at a first predetermined temperature, and etching a component A in the MAX phase material to obtain a two-dimensional material containing MX. The method avoids requiring the steps such as repeated cleaning, ultrasonic and centrifugal separation, and drying in preparing MXene in a liquid-phase method, greatly simplifies a preparation process, reduces the preparation cost, can achieve industrial macro preparation of MXene, and lays a foundation for application of MXene in different fields.

The present application claims priority to Chinese Patent Application No. 202011466046.4 filed with the China National Intellectual Property Administration on Dec. 14, 2020, entitled “Method and System for Fabricating a Two-Dimensional Material by Gas Phase Method”, the entire disclosure of which is incorporated herein by reference as part of the present application.

### TECHNICAL FIELD

The present disclosure relates to the field of fabrication of two-dimensional materials, in particular to a method and system for fabricating a two-dimensional material by using gas phase method.

### BACKGROUND

Two-dimensional transition metal carbides, nitrides, or carbonitrides are also known as Mxenes, because they have two-dimensional structures similar to that of graphene. A single MXene layer has a thickness of about 1 nm, but the transverse dimension thereof can be up to tens of microns or more. Such unique structure and surface characteristic enable MXenes to exhibit unique superior properties, such as, electric property, optical property, thermal stability, etc., and have a potential application prospect in the fields of energy storage, catalyzation, absorption, etc.

At present, the most classic and common method for fabricating MXene two-dimensional materials is the hydrofluoric acid (HF) etching method: taking a MAX phase material as a raw material and etching an A component from the raw material with HF to obtain a two-dimensional MXene material; wherein the MAX phase material is a layered ceramic material, M refers to a transition metal element including Sc, Ti, V, Cr, Zr, Nb, Mo, Hf, Ta, etc.; A refers primarily to an element of Group IIIA and the fourth main group, such as Al, Ga, In, Tl, Si, Ge, Sn, Pb, etc.; X represents C or N; and n equals 1, 2, or 3. The MAX phase materials involve a wide range of materials, and the material types included are shown in literatures (Maxim S, Varun N, Sankalp K, et al., Trends in Chemistry, 2019, 1(2):210-223).

Taking Ti₃AlC₂ as an example of the MAX phase material, Ti₃AlC₂ is soaked in an HF solution (at a concentration of 50%) for 2 hours to etch the Al atom(s) from the Ti₃AlC₂, so that Ti₃C₂ is fabricated (Naguib M, Kurtoglu M, Presser V, et al. Advanced Materials, 2011, 23(37): 4248-4253). Since HF has strong corrosion and high toxicity when directly used, the researchers replace the HF with the HCl solution and fluoride salt(s) as the etching agent to fabricate MXenes (Ghidiu M, Lukatskaya M R, Zhao M Q, et al. Nature, 2014, 516(7529): 78). MXene two-dimensional materials, such as, Ti₂C, Ta₄C₃, Ti₃CN, V₄C₃, etc., are fabricated by similar methods.

However, such method for fabricating MXenes directly or indirectly uses the HF acid liquid with strong corrosion and high toxicity, so that it is difficult to ensure the safety during the fabrication. Meanwhile, since it is a liquid phase reaction, the prepared MXenes are dispersed in a highly concentrated acid liquid, and have to undergo the steps of repeated washing, ultrasonication, centrifugal separation, drying, etc. to obtain a powdery MXene product. The complicated process steps result in difficulty in fabrication of MXenes in large scale and extremely high fabrication cost, which seriously limits the application prospect of MXenes. At present, the method and application of MXenes are still in the laboratory research stage.

### SUMMARY

To address the technical problem that the method for fabricating MXenes by liquid phase method is difficult to industrialize for large-scale production, the present disclosure provides a method for fabricating a two-dimensional material by using gas phase method. The method comprises a gas phase etching step in which a gas having an etching effect reacts with a MAX phase material at a first predetermined temperature to etch an A component from the MAX phase material, and a two-dimensional material containing MX is obtained.

In some exemplarily implementations, the gas having the etching effect comprises at least one selected from the group of a halogen elementary substance, a halogen hydride, and a nitrogen-family hydride.

In some exemplarily implementations, the halogen elementary substance is Br₂ or I₂; the halogen hydride is HF, HCl, HBr or HI; and the nitrogen-family hydride is NH₃ or H₃P.

In some exemplarily implementations, the first predetermined temperature is from 500° C. to 1200° C.

In some exemplarily implementations, the gas in the gas phase etching step further comprises a carrier gas, the carrier gas at least one selected from the group of helium gas, neon gas, argon gas, krypton gas, xenon gas, and nitrogen gas.

In some exemplarily implementations, the gas having the etching effect is produced by thermal decomposition or sublimation of a solid, or by gasification of a liquid; or the gas having the etching effect is produced by a chemical reaction of a compound with an acid solution.

In some exemplarily implementations, the solid is a halogen ammonium compound or an iodine elementary substance; the liquid is a halogen acid solution; and the compound is a halogen metal salt.

In some exemplarily implementations, the method of the present disclosure further comprises an adjustment step in which the two-dimensional material containing MX reacts with a functional gas at a second predetermined temperature, the functional gas is an elemental substance or a hydride of the fourth main group, the fifth main group, or the sixth main group, and the adjustment step results in a two-dimensional material containing an element of the fourth, fifth, or sixth main groups.

In some exemplarily implementations, the element of the fourth, fifth, or sixth main groups replaces part or all of functional groups of the two-dimensional material containing MX to obtain a two-dimensional material containing a functional group of the element of the fourth, fifth, or sixth main groups.

In some exemplarily implementations, the second predetermined temperature is from 100° C. to 600° C.

In some exemplarily implementations, the element of the fourth, fifth, or sixth main groups replaces part or all of X component in the two-dimensional material containing MX, and the adjustment step results in a two-dimensional material containing the element of the fourth, fifth, or sixth main groups.

In some exemplarily implementations, the second predetermined temperature is from 600° C. to 1500° C.

In some exemplarily implementations, a functional gas is provided in the gas phase etching step, the functional gas is an elemental substance or a hydride of the fourth, fifth, or sixth main groups, so that the MAX phase material undergoes a gas phase etching reaction with the gas having the etching effect and simultaneously the two-dimensional material containing MX and the functional gas undergo a functional-group adjustment reaction and/or a conversion reaction; the gas phase etching step results in a two-dimensional material containing an element of the fourth, fifth, or sixth main groups.

In some exemplarily implementations, the elemental substance of the fourth main group is C, Si or Ge; the hydride of the fourth main group is CH₄, C₂H₈, C₂H₄, H₄Ge or H₄Si; the elemental substance of the fifth main group is P; the hydride of the fifth main group is NH₃ or PH₃; the elemental substance of the sixth main group is O₂, S, Se or Te; and the hydride of the sixth main group is H₂S, H₂Se or H₂Te.

In some exemplarily implementations, in the MAX phase material, M represents a transition metal element; A represents a main group element and/or a transition metal element; and X represents at least one selected from the group of carbon, nitrogen, and boron.

The present disclosure further provides a system for fabricating a two-dimensional material by using gas phase method, comprising: a reaction device, having a temperature-controllable reaction chamber configured for reacting a gas having an etching effect with a MAX phase material at a predetermined temperature to obtain a two-dimensional material containing MX; and a first gas device configured for introducing the gas having the etching effect into the reaction device.

In some exemplarily implementations, the first gas device is a gas-production device configured for producing the gas having the etching effect by thermal decomposition or sublimation of a solid; or by gasification of a liquor; or by a chemical reaction of a compound with an acid liquor.

In some exemplarily implementations, the first gas device is provided in the reaction chamber.

In some exemplarily implementations, the system further comprises an exhaust-gas absorption device configured for absorbing unreacted portion of the gas having the etching effect in the reaction device; and/or an exhaust-gas recovery device configured for storing unreacted gas or re-introducing the unreacted gas into the reaction device.

In some exemplarily implementations, the system further comprises a second gas device configured for introducing a second gas into the reaction device for participate in the reaction.

The present disclosure further provides use of the two-dimensional material fabricated by the aforementioned method for fabricating the two-dimensional material by using gas phase method in supercapacitors, metal batteries, catalyzation, electromagnetic shielding, wave-absorbing coating, electronic devices, or as superconducting materials.

The beneficial effects of the present disclosure are as follows:
(1) The gas having the etching effect reacts with the MAX material to etch the A component from the MAX phase material to obtain the two-dimensional material containing MX, which avoids the steps of repeated washing, ultrasonication, centrifugal separation, drying, etc., during the fabrication of MXenes by using a liquid phase method, thereby greatly simplifying the fabrication method, reducing the fabrication cost, and can realize a large-scale industrial production of MXenes, so as to lay the foundation for applications of MXenes in various fields.
(2) The fabrication method of the present disclosure is also applicable to the MAX materials in which X is CN or N element, so that MXenes in which X is CN or N element can be obtained by etching, while such types of MXenes are difficult to obtain via etching by conventional liquid phase method.
(3) The fabrication method of the present disclosure can achieve a rapid etching (within ˜30 min), so that the fabrication efficiency of MXenes are greatly increased.
(4) The present disclosure further provides a method for modifying an MXene material in which an MXene material reacts with an elemental substance or a hydride of element of the fourth, fifth or sixth main groups to obtain a novel MXene material. The fabrication method is simple and prone to batch production.

### BRIEF DESCRIPTION OF THE DRAWINGS

FIG. 1 to FIG. 5 show schematic diagrams of a system for fabricating a two-dimensional material by using gas phase method according to Embodiment 2 of the present disclosure;

FIG. 6 shows SEM photographs of (a) block Ti₃AlC₂, and (b) Ti₃C₂Tₓ fabricated by the reaction of HCl gas with Ti₃AlC₂ in Embodiment 3 of the present disclosure;

FIG. 7 shows an XRD spectrum of Ti₃C₂Tₓ fabricated by the reaction of Ti₃AlC₂ with HCl gas and an XRD spectrum of Ti₃AlC₂ in Embodiment 3 of the present disclosure;

FIG. 8 shows (a) a STEM image of Ti₃C₂ Tₓ, and distribution diagrams of (b) Ti, (c) C, and (d) Cl elements of Ti₃C₂Tₓ in Embodiment 3 of the present disclosure;

FIG. 9 shows a SEM photograph of Ti₃CNTₓ fabricated by the reaction of HCl gas with Ti₃AlCN in Embodiment 4 of the present disclosure;

FIG. 10 shows an XRD spectrum of Ti₃CNTₓ fabricated by the reaction of Ti₃AlCN with HCl gas and an XRD spectrum of Ti₃AlCN in Embodiment 4 of the present disclosure;

FIG. 11 shows (a) a STEM image of Ti₃CNTₓ, and distribution diagrams of (b) Ti, (c) C, (d) N, and (e) Cl elements of Ti₃CNTₓ in Embodiment 4 of the present disclosure;

FIG. 12 shows SEM photographs of (a) block (Mo_{2/3}Y_{1/3})₂AlC and (b) (Mo_{2/3}Y_{1/3})₂CTₓ fabricated by the reaction of HCl gas with (Mo_{2/3}Y_{1/3})₂AlC in Embodiment 5 of the present disclosure;

FIG. 13 shows an XRD spectrum of (Mo_{2/3}Y_{1/3})₂CTₓ fabricated by the reaction of (Mo_{2/3}Y_{1/3})₂AlC with HCl gas and an XRD spectrum of (Mo_{2/3}Y_{1/3})₂AlC in Embodiment 5 of the present disclosure;

FIG. 14 shows (a) a STEM image of (Mo_{2/3}Y_{1/3})₂CTₓ, and distribution diagrams of (b) Mo, (c) Y, (d) C, and (e) Cl elements of (Mo_{2/3}Y_{1/3})₂CTₓ in Embodiment 5 of the present disclosure;

FIG. 15 shows SEM photographs of (a) block Ti₄AlN₃, (b) Ti₄N₃Tₓ fabricated by the reaction of Ti₄AlN₃ with HCl gas, and (c) Ti₄N₃—O₂ fabricated by the reaction of Ti₄AlN₃ with HCl gas and O₂ in Embodiment 6 of the present disclosure;

FIG. 16 shows XRD spectra of block Ti₄AlN₃, Ti₄N₃Tₓ fabricated by the reaction of Ti₄AlN₃ with HCl gas, and Ti₄N₃—O₂ fabricated by the reaction of Ti₄AlN₃ with HCl gas and O₂ in Embodiment 6 of the present disclosure;

FIG. 17 shows a high-resolution Cl 2p XPS spectrum of Ti₄N₃Tₓ fabricated by the reaction of Ti₄AlN₃ with HCl gas in Embodiment 6 of the present disclosure;

FIG. 18 shows (a) a STEM image of Ti₄N₃Tₓ (T═O), and distribution diagrams of (b) Ti, (c) N, and (d) 0 elements of Ti₄N₃Tₓ (T═O) in Embodiment 6 of the present disclosure;

FIG. 19 shows SEM photographs of (a) TiNbAlC, (b) TiNbC—Cl₂, and (c) TiNbC—S₂ in Embodiment 7 of the present disclosure;

FIG. 20 shows XRD spectra of TiNbAlC, TiNbC—Cl₂ and TiNbC—S₂ in Embodiment 7 of the present disclosure;

FIG. 21 shows (a) a STEM image of TiNbC—Cl₂, and distribution diagrams of (b) Ti, (c) Nb, (d) C and (e) Cl elements of TiNbC—Cl₂ in Embodiment 7 of the present disclosure;

FIG. 22 shows (a) a STEM image of TiNbC—S₂, and (b) a distribution diagram of S element of TiNbC—S₂ in Embodiment 7 of the present disclosure;

FIG. 23 shows SEM photographs of (a) Ta₂AlC and (b) Ta₂C-Tₓ in Embodiment 8 of the present disclosure;

FIG. 24 shows SEM photographs of (a) Nb₂AlC and (b) Nb₂C-Tₓ in Embodiment 9 of the present disclosure;

FIG. 25 shows SEM photographs of (a) Nb₂AlC and (b) Nb₂C—Cl₂ in Embodiment 10 of the present disclosure;

FIG. 26 shows SEM photographs of (a) Mo₂C—S₂ in Embodiment 11 of the present disclosure and (b) MoS₂ in Embodiment 12 of the present disclosure;

FIG. 27 shows an XRD spectrum of MoS₂ in Embodiment 12 of the present disclosure;

FIG. 28 shows (a) a SEM photograph, (b) an XRD spectrum, and (c) a high-resolution S 2p XPS spectrum of Ti₃C₂—S₂ in Embodiment 13 of the present disclosure;

FIG. 29 shows XRD spectra of (a) Ti₃C₂—Se₂, (b) Ti₃C₂—Te₂ and (c) Ti₃C₂—P₂ fabricated by the reaction of Ti₃AlC₂ with HCl and S, Se, Te in Embodiment 14 of the present disclosure;

FIG. 30 shows high-resolution (a) Se 3d XPS spectrum, (b) Te 3d XPS spectrum, and (c) P 2p XPS spectrum of Ti₃C₂Tₓ fabricated by the reaction of Ti₃AlC₂ with HCl and S, Se, Te in Embodiment 14 of the present disclosure;

FIG. 31 shows (a) a SEM photograph, (b) an XRD spectrum, and (c) a high-resolution S 2p XPS spectrum of Ti₃C₂—S₂ in Embodiment 15 of the present disclosure;

FIG. 32 shows XRD spectra of (a) Ti₃CN—Se₂, (b) Ti₃CN—Te₂ and (c) Ti₃CN—P₂ fabricated by the reaction of Ti₃AlCN with HCl and S, Se, Te in Embodiment 16 of the present disclosure;

FIG. 33 shows high-resolution (a) Se 3d XPS spectrum, (b) Te 3d XPS spectrum, and (c) P 2p XPS spectrum of Ti₃CNTₓ fabricated by the reaction of Ti₃AlCN with HCl and S, Se, Te in Embodiment 16 of the present disclosure;

FIG. 34 shows XRD spectra of (a) Nb₂C—Se₂, (b) Nb₂C—Te₂ and (c) Nb₂C—P₂ fabricated by the reaction of Nb₂AlC with HCl and S, Se, Te in Embodiment 17 of the present disclosure;

FIG. 35 shows high-resolution (a) Se 3d XPS spectrum, (b) Te 3d XPS spectrum, and (c) P 2p XPS spectrum of Nb₂CTₓ fabricated by the reaction of Nb₂AlC with HCl and S, Se, Te in Embodiment 17 of the present disclosure;

FIG. 36 shows SEM photographs of (a) block Nb₄AlC₃ and (b) Nb₄C₃Tₓ and XRD spectra of (c) Nb₄C₃Tₓ and Nb₄AlC₃ in Embodiment 18 of the present disclosure;

FIG. 37 shows (a) a STEM image of Nb₄C₃Tₓ, and distribution diagrams of (b) Nb, (c) C, and (d) Cl elements of Nb₄C₃Tₓ in Embodiment 18 of the present disclosure;

FIG. 38 shows (a) a SEM photograph, (b) an XRD spectrum, and (c) a high-resolution S 2p XPS spectrum of Nb₄C₃—S₂ in Embodiment 19 of the present disclosure;

FIG. 39 shows XRD spectra of (a) Nb₄C₃—Se₂, (b) Nb₄C₃—Te₂ and (c) Nb₄C₃—P₂ fabricated by the reaction of Nb₄AlC₃ with HCl and S, Se, Te in Embodiment 20 of the present disclosure;

FIG. 40 shows high-resolution (a) Se 3d XPS spectrum, (b) Te 3d XPS spectrum, and (c) P 2p XPS spectrum of Nb₄C₃Tₓ fabricated by the reaction of Nb₄AlC₃ with HCl and S, Se, Te in Embodiment 20 of the present disclosure;

FIG. 41 shows XRD spectra of (a) TiNbC—Se₂, (b) TiNbC—Te₂ and (c) TiNbC—P₂ fabricated by the reaction of TiNbAlC with HCl and S, Se, Te in Embodiment 21 in the present disclosure;

FIG. 42 shows high-resolution (a) Se 3d XPS spectrum, (b) Te 3d XPS spectrum, and (c) P 2p XPS spectrum of TiNbCTₓ fabricated by the reaction of TiNbAlC with HCl and S, Se, Te in Embodiment 21 of the present disclosure;

FIG. 43 shows (a) a SEM photograph, (b) an XRD spectrum, and (c) a high-resolution S 2p XPS spectrum of Ta₂C—S₂ in Embodiment 22 of the present disclosure;

FIG. 44 shows XRD spectra of (a) Ta₂C—Se₂, (b) Ta₂C—Te₂ and (c) Ta₂C—P₂ fabricated by the reaction of Ta₂AlC with HCl and S, Se, Te in Embodiment 23 of the present disclosure;

FIG. 45 shows high-resolution (a) Se 3d XPS spectrum, (b) Te 3d XPS spectrum, and (c) P 2p XPS spectrum of Ta₂CTₓ fabricated by the reaction of Ta₂AlC with HCl and S, Se, Te in Embodiment 23 of the present disclosure;

FIG. 46 shows (a) a SEM photograph, (b) an XRD spectrum, and (c) a high-resolution Cl 2p XPS spectrum of Ta₄C₃Tₓ fabricated by HCl gas with Ta₄AlC₃ in Embodiment 24 of the present disclosure;

FIG. 47 shows (a) a SEM photograph, (b) an XRD spectrum, and (c) a high-resolution S 2p XPS spectrum of Ta₄C₃—S₂ in Embodiment 25 of the present disclosure;

FIG. 48 shows (a) a SEM photograph, (b) an XRD spectrum, and (c) a high-resolution S 2p XPS spectrum of Ti₄N₃—S₂ in Embodiment 26 of the present disclosure;

FIG. 49 shows XRD spectra of (a) Ti₄N₃—Se₂, (b) Ti₄N₃—Te₂ and (c) Ti₄N₃—P₂ fabricated by the reaction of Ti₄AlN₃ with HCl and S, Se, Te in Embodiment 27 of the present disclosure;

FIG. 50 shows high-resolution (a) Se 3d XPS spectrum, (b) Te 3d XPS spectrum, and (c) P 2p XPS spectrum of Ti₄N₃Tₓ fabricated by the reaction of Ti₃AlN₃ with HCl and S, Se, Te in Embodiment 27 of the present disclosure;

FIG. 51 shows (a) a SEM photograph, (b) an XRD spectrum, and (c) a high-resolution Cl 2p XPS spectrum of HCl gas with Ti₂AlC in Embodiment 28 of the present disclosure;

FIG. 52 shows (a) a SEM photograph, (b) an XRD spectrum, and (c) a high-resolution S 2p XPS spectrum of Ti₂C—S₂ in Embodiment 29 of the present disclosure;

FIG. 53 shows (a) a SEM photograph and (b) an XRD spectrum of Ti₂NTₓ fabricated by the reaction of HCl gas with Ti₂AlN in Embodiment 30 of the present disclosure;

FIG. 54 shows (a) a STEM image of Ti₂NTₓ, and distribution diagrams of (b) Ti, (c) N, and (d) Cl elements of Ti₂NTₓ in Embodiment 30 of the present disclosure;

FIG. 55 shows (a) a SEM photograph, (b) an XRD spectrum, and (c) a high-resolution S 2p XPS spectrum of Ti₂N—S₂ in Embodiment 31 of the present disclosure;

FIG. 56 shows (a) a SEM photograph and (b) an XRD spectrum of Ti₃C₂Tₓ fabricated by HCl gas with Ti₃SiC₂ in Embodiment 32 of the present disclosure;

FIG. 57 shows (a) a STEM image of Ti₃C₂Tₓ, and distribution diagrams of (b) Ti, (c) C, and (d) Cl elements of Ti₃C₂Tₓ in Embodiment 32 of the present disclosure;

FIG. 58 shows (a) a SEM photograph of Mo₂CTₓ fabricated by the reaction of HCl gas with Mo₂Ga₂C in Embodiment 33 of the present disclosure, and (b) XRD spectra of Mo₂CTₓ and Mo₂Ga₂C;

FIG. 59 is (a) a SEM image of Mo₂CTₓ, and distribution diagrams of (b) Mo, (c) C, and (d) Cl of Mo₂CTₓ in Embodiment 33 of the present disclosure;

FIG. 60 shows (a) a SEM photograph, (b) an XRD spectrum, and (c) a high-resolution C is XPS spectrum of Ti₄N₃-C₂ in Embodiment 34 of the present disclosure.

### REFERENCE NUMERALS

100—gas having an etching effect; 10—reaction device; 11—raw material layer; 20—absorption device; 30—first gas device; 31—gas-production device; 311—acid liquid vessel; 312—reactor; 31—control device; 40—carrier gas device; 50—exhaust-gas recovery device; 60—second gas device.

### DETAILED DESCRIPTION

Hereinafter the technical solutions are described by reference to specific examples. It should be understood that one or more steps mentioned in the present disclosure do not exclude the presence of additional method(s) and step(s) before or after the combination of the steps, or additional method(s) and step(s) can be further inserted between these steps expressly mentioned. It should also be understood that these examples are only for the purpose of illustrating the present disclosure, and not for limiting the scope of the present disclosure. Unless otherwise stated, the numbering of each step of the method is only for the purpose of identifying each step of the method, rather than limiting the arrangement order of each method or limiting the implementation scope of the present disclosure, and the change or adjustment to their relative relationship without any substantive change of technical concept can also be considered as being within the implementation scope of the present disclosure. The sources of raw materials or instruments used in the embodiments are not limited in particular, and can be commercially available or fabricated in accordance with conventional methods that are well known by an ordinary skilled in the art.

### Embodiment 1

The embodiment provides a method for fabricating a two-dimensional material by using gas phase method, and the method includes:

a gas phase etching step: a gas having an etching effect reacts with a MAX phase material at a first predetermined temperature and an A component is etched from the MAX phase material, so as to obtain a two-dimensional material containing MX (MXene).

It should be noted that the MAX phase material, which is the raw material of the present disclosure, has a chemical formula of Mₙ₊₁AXₙ, wherein M is at least one selected from the group of transition metal elements, A is at least one selected from elements of Groups VIIB, VIII, IB, IIB, IIIA, IVA, VA and VIA, and X is at least one selected from the group of carbon, nitrogen, and boron elements.

In some exemplarily implementations, M transition metal element is at least one selected from elements of Groups IIIB, IVB, VB and VIB. Generally, the M element includes but is not limited to, at least one selected from the group of scandium, yttrium, titanium, zirconium, hafnium, vanadium, niobium, tantalum, chromium, molybdenum, tungsten, and lanthanide element (lanthanum, cerium, praseodymium, neodymium, promethium, samarium, europium, gadolinium, terbium, dysprosium, holmium, erbium, thulium, ytterbium or lutetium); the A element includes but is not limited to, at least one selected from the group of aluminum, silicon, phosphorus, sulfur, manganese, iron, cobalt, nickel, copper, zinc, gallium, germanium, arsenic, selenium, ruthenium, rhodium, palladium, cadmium, indium, tin, antimony, osmium, iridium, platinum, gold, mercury, thallium, lead, bismuth, polonium and astatine. The MAX phase material involves a wide range of materials, all the MAX phase materials found before or after the filing date of the present disclosure and the MXene materials fabricated by the method of the present disclosure belong to the protection scope of the accompanying claims of the present disclosure.

In the embodiments of the present disclosure, the gas having the etching effect includes: at least one selected from the group of a halogen elementary substance, a halogen hydride, and a nitrogen-family hydride, all of which are able to react with the A component in the MAX phase material under certain reaction condition to produce a gas phase product that is then removed from the reaction system, thereby achieving a partial or complete etching of the A component to obtain the two-dimensional material containing MX (also referred to as “MX-containing 2D material”). The MX-containing 2D material does not include any solid impurities and has superior characteristic of high purity. Preferably, the halogen elementary substance includes Br₂ or I₂; the halogen hydride includes HF, HCl, HBr or HI; and the nitrogen-family hydride includes NH₃ or H₃P.

In some exemplarily implementations, in the gas phase etching step, the first predetermined temperature is from 500° C. to 1200° C. The reaction temperature is associated with the bonding energy between the A element and the M and X elements in the MAX phase material. The higher the bonding energy, the higher the required reaction temperature. Preferably, the reaction temperature is from 600° C. to 800° C.

In some exemplarily implementations, the gas in the gas phase etching step further includes a carrier gas. The carrier gas is an inert gas that does not participate in the gas phase etching reaction and includes at least one selected from the group of helium gas, neon gas, argon gas, krypton gas, xenon gas, and nitrogen gas. The addition of the carrier gas dilutes the concentration of the gas having the etching effect in the mixed gas, and in turn controls the rate of the gas phase etching reaction.

In some exemplarily implementations, the gas having the etching effect is produced by thermal decomposition or sublimation of a solid, or by gasification of a liquid, wherein the solid preferably includes a halogen ammonium compound. For example, the halogen hydride is produced by thermally decomposing the solid halogen ammonium compound (e.g., NH₄F, NH₄Cl, NH₄Br, NH₄I, etc.). When the halogen ammonium compound is thermally decomposed, an ammonia gas and a halogen hydride gas are produced and there aren't any new solid impurities introduced into the gas phase reaction. Optionally, it further includes: a solid iodine elementary substance, which becomes gas phase by heating sublimation; or a halogen acid solution, which is gasified to produce halogen elementary substance or a halogen hydride gas.

In some exemplarily implementations, the gas having the etching effect is produced by a chemical reaction of a compound with an acid solution. For example, the halogen hydride gas is produced by the chemical reaction of a halogen metal salt with an acid solution. Optionally, the chemical reaction includes, but is not limited to, NaCl+H₂SO₄=NaHSO₄+HCl↑, NaBr+H₃PO₄═NaH₂PO₄+HBr↑, CaF₂+H₂SO₄═CaSO₄+2HF, NaI+H₃PO₄═NaH₂PO₄+HI↑, and so on.

In some exemplarily implementations, the present disclosure further includes an adjustment step: the MX-containing 2D material reacts with a functional gas at a second predetermined temperature, wherein the functional gas includes an elementary substance or a hydride of an element of the fourth, fifth or sixth main groups to obtain two-dimensional materials containing the element of the fourth, fifth or sixth main groups, thereby achieving the modification of the two-dimensional material. Preferably, the elemental substance of the fourth main group includes C, Si or Ge; the hydride of the element of the fourth main group includes CH₄, C₂H₈, C₂H₄, H₄Ge or H₄Si; the elemental substance of the fifth main group includes P; the hydride of the element of the fifth main group includes NH₃ or PH₃; the elemental substance of the sixth main group includes O₂, S, Se or Te; and the hydride of element of the sixth main group includes H₂S, H₂Se or H₂Te.

In some exemplarily implementations, the gas in the gas phase etching step further includes a functional gas, and the function gas includes an elemental substance or a hydride of an element of the fourth, fifth or sixth main groups, so that the MAX phase material undergoes the gas phase etching reaction with the gas having the etching effect and simultaneously the MX-containing 2D material undergoes a functional-group adjustment reaction and/or a conversion reaction with the functional gas. Thus, the two-dimensional material containing the element of the fourth, fifth or sixth main groups is obtained in the gas phase etching step, that is, the object of the adjustment step is simultaneously achieved in the gas phase etching step. Preferably, the reaction temperature is set from 500° C. to 700° C., such that the functional-group adjustment reaction primarily occurs, so as to obtain the MX two-dimensional material containing functional group of the element of the fourth, fifth or sixth main groups. Preferably, the reaction temperature is set from 700° C. to 1200° C., such that the conversion reaction primarily occurs, so as to obtain a novel two-dimensional material containing the element of the fourth, fifth or sixth main groups.

It should be noted that two types of reaction occur in the adjustment step. One is to replace part or all of functional groups in the MX-containing 2D material with an element of the fourth, fifth or sixth main groups, so as to obtain the MX two-dimensional material containing the functional group of the element of the fourth, fifth or sixth main groups. Preferably, such type of reaction primarily occurs at a relatively low reaction temperature (from 100° C. to 800° C.). The other is to replace part or all of the X component in the MX-containing 2D material with an element of the fourth, fifth or sixth main groups, so as to obtain the novel two-dimensional material containing the element of the fourth, fifth or sixth main groups. Preferably, such type of reaction primarily occurs at a relatively high reaction temperature (from 600° C. to 1500° C.).

It should also be noted that the MX-containing 2D material obtained in the gas phase etching step of the present disclosure has, on its surface, a functional group (such as, —F, —Cl, —Br, —I, —P, —N, etc.) introduced by the gas having the etching effect. After the gas phase etching step, the reaction temperature is directly adjusted to the second predetermined temperature and the functional gas is introduced, so that the functional-group adjustment reaction occurs, and the functional group carried by the MX-containing 2D material can directly react with the functional gas to achieve a technical effect of adjusting specific functional group. However, in the related technology, the MX material fabricated by liquid phase method have —F, —OH, —O functional groups on its surfaces and is more prone to be oxidized or hydrolyzed to become a transition metal oxide, so that it is difficult to achieve the object of adjusting the functional group on the MX material.

Preferably, the gases in the gas phase etching step and the adjustment step of the present disclosure includes a carrier gas, wherein the volume content of the carrier gas is from 20% to 80%. The gas phase etching step of the present disclosure can control the etching rate of the MAX phase material by means of the reaction time. In the adjustment step, the substitution degree of the functional group or the replacement degree the X element can be controlled by means of the reaction time in the adjustment step. Generally, the reaction time of the gas phase etching step and the adjustment step is from 5 minutes (i.e., 5 min) to 6 hours (i.e., 6 h). Preferably, in the gas phase etching step, the reaction time of 20 min to 40 min can achieve a complete etching; and in the adjustment step, the reaction time of 20 min to 60 min can achieve a complete substitution or replacement. In the present disclosure, the heating rate of conventional technical means is from 2° C./min and 20° C./min, and the experimental reaction is carried out at atmospheric pressure.

### Embodiment 2

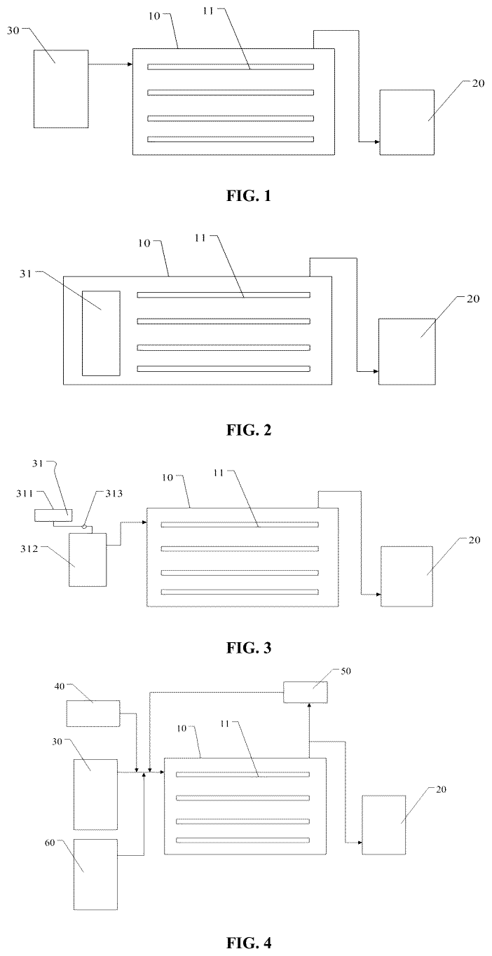

The embodiment provides a system for fabricating a two-dimensional material by using gas phase method, as shown in FIG. 1, the system includes a reaction device 10, an exhaust-gas absorption device 20, and a gas device 30. The reaction device 10 is configured for enabling a gas 100 having an etching effect to react with a MAX phase material at a predetermined temperature, such that the A component is etched from the material by using the gas 100 having the etching effect and an MX-containing 2D material is obtained; the exhaust-gas absorption device 20 is used for absorbing excessive unreacted gas in the reaction device; and the gas device 30 is used for supplying the gas 100 having the etching effect into the reaction device 10.

A reaction chamber which is able to be closed is provided inside the reaction device 10, and at least one raw material layer 11 for disposing the MAX phase material is provided inside the reaction chamber. The gas 100 having the etching effect is introduced into a reaction space inside the reaction device 10, so that the gas having the etching effect in the gas phase can be reacted with the MAX phase material at a predetermined temperature. In the example as shown in FIG. 1, four raw material layers are provided, but the present disclosure is not limited thereto. Providing a plurality of raw material layers 11 in the reaction space allows to arrange more MAX phase materials, so as to produce more MX materials in one batch of gas etching reaction, so that a large-scale production of MX material is achieved and the fabrication cost of the MX materials is greatly reduced. The excessive gas in the gas phase reaction is absorbed by the exhaust-gas absorption device 20. In some exemplarily implementations, a basic liquid (e.g., a solution of NaOH, KOH, etc.) is provided inside the exhaust-gas absorption device 20 to absorb the excessive gas in the gas phase reaction by means of neutralization reaction.

The gas device 30 can be either a gas storage device, such as, a high-pressure gas tank; or a gas-production device 31, that is, a device through which a gas having the etching effect is produced.

Optionally, the gas-production device 31 is a device in which a gas is produced by thermal decomposition of a solid. Preferably, the solid is a halogen ammonium compound (e.g., NH₄F, NH₄C₁, NH₄Br, NH₄I, etc.). While being thermally decomposed, the halogen ammonium compound produces ammonia gas and halogen hydride gas, and there are not any new solid impurities introduced into the gas phase etching reaction. Excessive ammonia gas and halogen hydride gas are absorbed by the exhaust-gas absorption device 20. Optionally, it further includes: a solid iodine elementary substance, which becomes gas phase by heating sublimation, which also avoid the introduction of new solid impurity into the gas phase etching step.

In another exemplarily implementation, as shown in FIG. 2, the gas-production device 31 is provided inside the reaction chamber of the reaction device 10, so that under the heating of the reaction device 10, the thermal decomposition of a solid occur to produce the gas having the etching effect. In this way, the produced gas having the etching effect directly enters into the reaction chamber of the reaction device 10 and it is not necessary to pass through any pipelines.

In another exemplarily implementation, the gas-production device 31 involves a chemical reaction of a compound with an acid solution, for example, a chemical reaction of a halogen metal salt with an acid solution so as to produce a halogen hydride gas. Optionally, the chemical reaction includes, but is not limited to, NaCl+H₂SO₄═NaHSO₄+HCl↑, NaBr+H₃PO₄═NaH₂PO₄+HBr↑, CaF₂+H₂SO₄═CaSO₄+2HF, NaI+H₃PO₄=NaH₂PO₄+HI↑, and so on. As shown in FIG. 3, the gas-production device 31 includes an acid liquid container 311, a reactor 312 and a control device 313. The metal salt of halogen element is placed in the reactor 312, and an acid solution in the acid liquid container is dripped into the reactor 312 under the control of the control device 313, so that the halogen metal salt is chemically reacted with the acid solution to produce the halogen hydride gas.

In the system for fabricating the two-dimensional material by using gas phase method according to the present disclosure, using the gas-production device 31 as the gas device 30 has the beneficial effect that: when required in use, it can be on-site produced, which avoids the safety problem, such as, leakage caused by the storage or delivery of halogen hydride gas during the production.

In another exemplarily implementation, the system for fabricating the two-dimensional material by using gas phase method according to the present disclosure further includes a carrier gas device 40 as shown in FIG. 4, the carrier gas device 40 is used for mixing a carrier gas with the gas having the etching effect via a pipeline to form a mixed gas which is then introduced into the reaction device 10 for reaction. The carrier gas refers to a gas which does not participate in the gas phase etching reaction, and includes, but is not limited to, helium gas, neon gas, argon gas, krypton gas, and xenon gas. By mixing the gas having the etching effect with the carrier gas, the content of the gas having the etching effect in the mixed gas is adjusted, so that the reaction rate of the gas phase etching reaction can be adjusted.

In another exemplarily implementation, the system for fabricating the two-dimensional material by using gas phase method according to the present disclosure further includes an exhaust-gas recovery device 50 as shown in FIG. 4, the exhaust-gas recovery device 50 is connected to an exhaust-gas outlet of the reaction device 10 via a pipeline and is used for recovering and storing excessive exhaust gas of the gas phase etching reaction; alternatively, the exhaust-gas recovery device 50 is used for re-introducing the excessive exhaust-gas of the gas phase etching reaction via a pipeline to the gas inlet of the reaction device 10 to enable the gas having the etching effect 100 to be recycled and reused, thereby increasing the gas utilization, reducing the handling throughput of the exhaust-gas absorption device 50 and in turn reducing the fabrication cost of the MX materials.

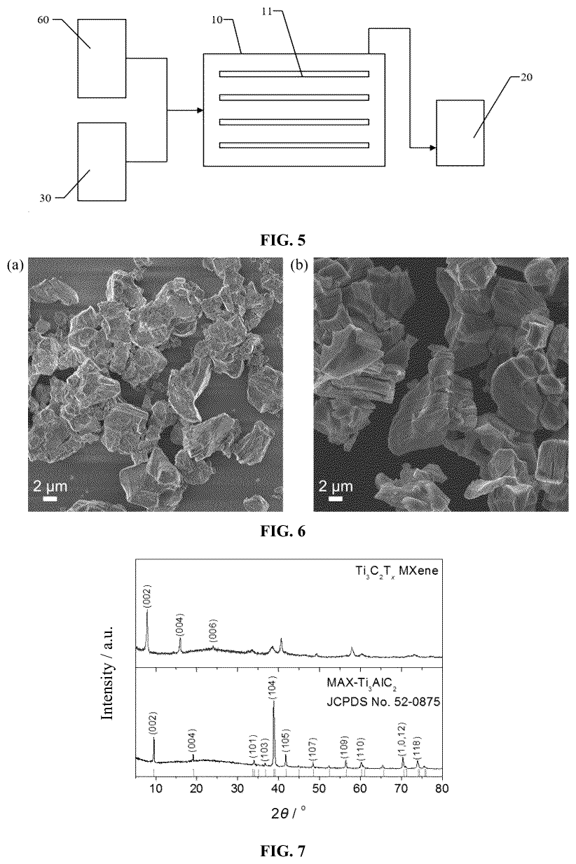

In another exemplarily implementation, the system for fabricating the two-dimensional material by using gas phase method according to the present disclosure further includes a second gas device 60 as shown in FIG. 4 and FIG. 5, the second gas device 60 is used for introducing a second gas into the reaction device 10. The second gas reacts with the MX-containing 2D material obtained in the gas phase etching step to adjust the types of the functional group on the surface of the MX material or replace part or all of the X element in the MX material, and in turn modify the performance of the material.

The method and system of the present disclosure can directly obtain powdery MX materials (MXenes) without any solid impurity, avoid the steps of repeated washing, ultrasonication, centrifugal separation, drying required during the fabrication of MXenes by using liquid phase method, greatly simplify the fabrication method, and reduce the fabrication cost. In the whole gas phase etching reaction, the excessive gas can be completely absorbed by the exhaust-gas absorption device 20, so that the whole reaction would not cause the problem of environmental contamination and meets the environmentally friendly requirement of industrial production.

### Embodiment 3

To better illustrate the technical characteristics of the present disclosure, the method for fabricating a two-dimensional material by using gas phase method according to the present disclosure is illustrated below by taking an example of using Ti₃AlC₂ as the MAX phase material and using the commercially available HCl liquefied gas as the halogen hydride gas. The selected reaction system is shown in FIG. 1 of Embodiment 2, the reaction device 10 is a tubular furnace, and the first gas device 30 is a high-pressure gas cylinder containing HCl gas. The method includes steps of:
1) placing powdery Ti₃AlC₂ inside the reaction device 10;
2) introducing the HCl gas into the reaction device 10 for a period of time such that the reaction chamber inside the reaction device 10 is fully filled with the HCl gas, and then closing the reaction chamber; and
3) heating the inside of the reaction device 10 to 700° C. and keeping for 10 min, such that the gas phase etching reaction occurs and a target product is obtained;

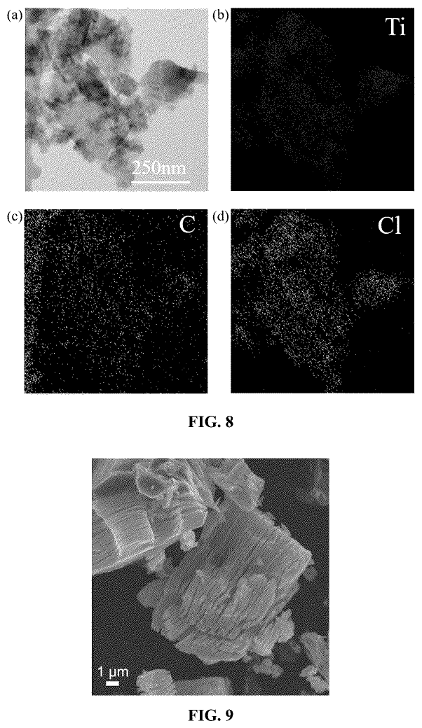

The target product is taken out after the reaction device is naturally cooled to room temperature. The MAX phase material Ti₃AlC₂ and the target product are subject to scanning electron microscope (SEM) test, respectively, and the results are shown in (a) and (b) of FIG. 6. By comparison, it can be seen that the morphology of Ti₃AlC is a three-dimensional block structure, while the target product exhibits a layer structure that is obviously similar to accordion-like shape. The MAX phase material Ti₃AlC₂ and the target product are subject to X-ray diffraction (XRD) analysis, and the results are shown in FIG. 7. By comparison, the (002) peak of the raw material Ti₃AlC₂ appears at 9.5°, while the (002) peak of the target product obtained after the reaction with the HCl gas is shifted to a low angle of 7.9°. It indicates that the HCl gas etches the Al element from the Ti₃AlC₂ during the gas phase etching reaction to produce the MX material (MXene) with a sheet-like layer structure and cause the increasing of the layer interval, which is consistent with the result of the SEM photograph of Ti₃C₂Tₓ. In the scanning transmission electron microscope (STEM) image of the transmission electron microscope (TEM) of the target product Ti₃C₂Tₓ shown in FIG. 8a, the presence of a large amount of two-dimensional ultrathin nanosheets indicates that the accordion-like Ti₃C₂Tₓ can be simply peeled off to obtain two-dimensional nanosheets, the two-dimensional nanosheets have uniform distribution of Ti and C elements (FIG. 8b and FIG. 8c) and further includes Cl element (FIG. 8d) which indicates that the resultant target product is the MX material (Ti₃C₂—Cl₂) containing Cl functional group.

It should be noted that in the embodiment, the gas phase etching reaction is carried out in the closed reaction chamber after the HCl gas is introduced into the reaction device. However, during the large-scale production of the present disclosure, the halogen hydride gas may also be continuously introduced into the reaction chamber, and the excessive gas is absorbed by the exhaust-gas absorption device or recycled and reused by the exhaust-gas recovery device.

### Embodiment 4

The embodiment takes an example of using Ti₃AlCN as the MAX phase material and using HCl gas as the gas having the etching effect. The fabrication method is the same as that of Embodiment 3, except that the gas etching reaction of the HCl gas with Ti₃AlCN is carried out at 800° C., and kept for 30 min to obtain a target product.

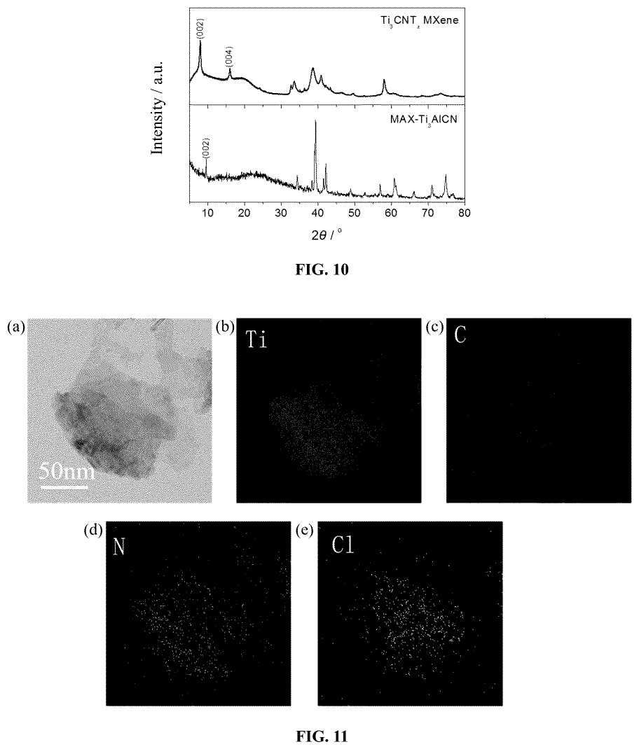

The target product is taken out after the reaction device is naturally cooled to room temperature. The target product is subject to SEM test for analysis. A large amount of expanded accordion-like structures appears in the SEM image (FIG. 9), which is different from the block layered morphology of the MAX phase powder, indicating that the Al between the Ti₃AlCN layers are etched by the reaction with HCl to obtain Ti₃CNTₓ (MXene). The MAX phase Ti₃AlCN and the target product are subject to X-ray diffraction (XRD) analysis, and the results are shown in FIG. 10. By comparison, the (002) peak of the raw material Ti₃AlCN appears at 9.5°, while the (002) peak of the target product obtained after the reaction with the HCl gas is shifted to a low angle of 8°, and a new (004) peak for the accordion-like layer structure appears in the reaction product. It indicates that the HCl gas etches the Al element from the Ti₃AlCN during the gas phase etching reaction to produce an MX material (MXene) with a sheet-like layer structure and cause the increasing of the layer interval, which is consistent with the expanded accordion-like structures in the result of the SEM photograph of Ti₃CNTₓ. A large amount of two-dimensional ultrathin nanosheets appears in the STEM image of the target product Ti₃CNTₓ, as shown in FIG. 11a, which indicates that the accordion-like Ti₃CNTₓ can be simply peeled off to obtain two-dimensional nanosheets, the two-dimensional nanosheets have uniform distribution of Ti, C and N elements (FIG. 11b, FIG. 11c, and FIG. 11d) and further includes Cl element (FIG. 11e), which indicates that the resultant target product is an MX material (Ti₃CN—Cl₂) containing Cl functional group.

### Embodiment 5

The embodiment takes an example of using (Mo_{2/3}Y_{1/3})₂AlC as the MAX phase material and using HCl gas as the halogen hydride gas to illustrate the fabrication method of the present disclosure. The selected reaction system is shown in FIG. 2 of Embodiment 1, the gas-production device 31 is provided inside in the reaction device 10, and the gas-production device 31 includes a channel for allowing the gas to enter into the reaction chamber of the reaction device. The process included the steps of:
1) placing powdery (Mo_{2/3}Y_{1/3})₂AlC inside the reaction device, placing solid NH₄C₁ inside the gas-production device 31, and closing the reaction chamber; and
2) heating the reaction device to 350° C. and keeping for 30 min to decompose the NH₄C₁ to NH₃ and HCl gas, and then heating to 650° C. and keeping for 30 min, such that the gas phase etching reaction occurs and a target product is obtained.

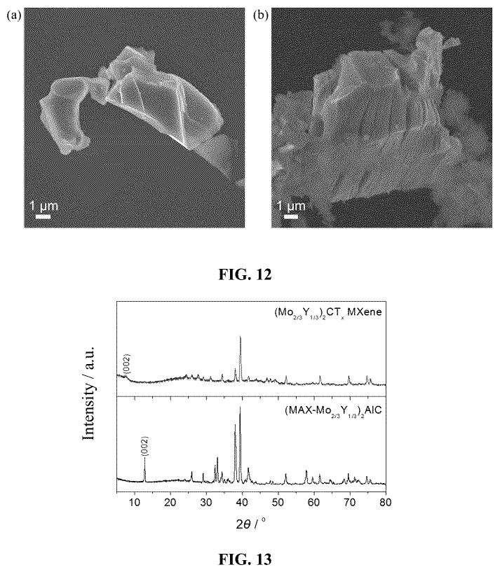

The target product is taken out after the reaction device is naturally cooled to room temperature. The target product obtained after the reaction of (Mo_{2/3}Y_{1/3})₂AlC with HCl is subject to SEM test, and the result is shown in FIG. 12. The target product obtained after the reaction exhibits an obvious accordion-like layer structure, which is obviously different from a block morphology of the raw material (Mo_{2/3}Y_{1/3})₂AlC. The (Mo_{2/3}Y_{1/3})₂AlC and the target product are subject to XRD analysis, and the results are shown in FIG. 13. By comparison, the (002) peak of the raw material (Mo_{2/3}Y_{1/3})₂AlC appears at 12.9°, while the (002) peak of the target product obtained after the reaction with the HCl gas is shifted to a low angle of 7.8°. It indicates that the HCl gas etches the Al element from (Mo_{2/3}Y_{1/3})₂AlC during the gas phase etching reaction, so as to produce an MX material (MXene) with a sheet-like layer structure and cause the increasing of the layer interval, which is consistent with the result of the SEM photograph. The presence of a large amount of two-dimensional ultrathin nanosheets in the STEM images of the target product (Mo_{2/3}Y_{1/3})₂CTₓ as shown in FIG. 14a indicates that the accordion-like (Mo_{2/3}Y_{1/3})₂CTₓ can be simply peeled off to obtain two-dimensional nanosheets, the two-dimensional nanosheets have uniform distribution of Ti, C and N elements (FIG. 14b, FIG. 14c, and FIG. 14d) and further includes Cl element (FIG. 14e), which indicates that the resultant target product is an MX material ((Mo_{2/3}Y_{1/3})₂C—Cl₂) containing Cl functional group.

### Embodiment 6

The embodiment takes an example of using Ti₄AlN₃ as the MAX phase material and using HCl gas as the halogen hydride gas to fabricate the two-dimensional material. The selected reaction system is shown in FIG. 5 in Embodiment 1, the reaction device 10 is a tubular furnace, the gas device 30 is the gas-production device 31, the halogen hydride gas is produced by the chemical reaction of a halogen metal salt with an acid solution: NaCl+H₂SO 4═NaHSO 4+HCl↑, and the gas device 60 is a high-pressure gas cylinder containing O₂ gas, except that the reaction of Ti₄AlN₃ with HCl results in a target product Ti₄N₃Tₓ, and the adjustment of surface functional group of the two-dimensional material Ti₄N₃Tₓ is achieved by using the second gas O₂. The method includes steps of:
1) placing powdery Ti₄AlN₃ inside the reaction device;
2) adding NaCl and H₂SO₄ into the gas-production device 31, controlling the H₂SO₄ to keep a certain dripping rate so that it continuously reacts with NaCl to produce HCl gas, and continuously introducing the HCL gas into the reaction chamber;
3) heating the inside of the reaction device to 650° C. and keeping for 30 min, such that the gas phase reaction occurs and a target product Ti₄N₃Tₓ is obtained, or continue to the next step of reaction;
4) after the completion of chlorine hydride reaction, closing the gas-production device to stop the introduction of HCl gas, and continuously introducing the O₂ from the second gas device into the reaction chamber;
5) adjusting the temperature inside the reaction device to 500° C. and keeping for 10 min, such that the gas phase reaction occurs and Ti₄N₃Tₓ (T═O) having oxygen functional group on its surface is obtained.

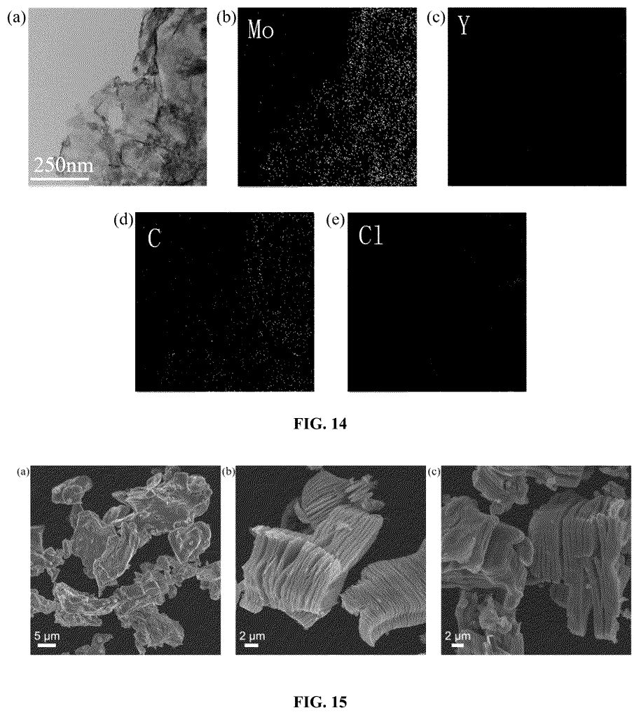

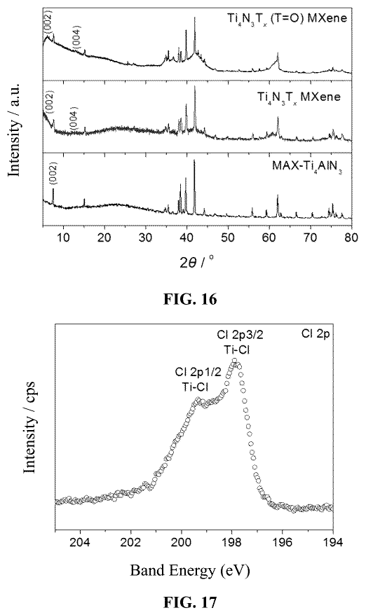

The target products are taken out after the reaction device is naturally cooled to room temperature. Ti₄AlN₃ and the two target products obtained after the reaction of Ti₄AlN₃ with HCl are subject to SEM test, and the results are shown in FIG. 15. The target products obtained after the reaction exhibit obvious accordion-like layer structures, and the accordion-like structure has obvious expansion structure stacked layer-by-layer, which is obviously different from the block morphology of the raw material Ti₄AlN₃. Ti₄AlN₃ and the two target products are subject to XRD analysis, and the results are shown in FIG. 16. By comparison, the (002) peak of the raw material Ti₄AlN₃ appears at 7.5°, but the target product obtained after the reaction with HCl and the target product obtained after subsequent O₂ treatment are shifted to a low angle of 6.1°. It indicates that the HCl gas etches the Al element from the Ti₄AlN₃ during the gas phase reaction to produce an MX material (MXene) with a sheet-like layer structure and cause the increasing of the layer interval, and the subsequent O₂ treatment doesn't change the crystal structure of Ti₄N₃, which is consistent with the result of the SEM photograph. The surface functional group of Ti₄N₃Tₓ obtained by the reaction of Ti₄AlN₃ with HCl is characterized by X-ray photoelectron spectrometer (XPS). As shown in FIG. 17, an obvious signal of Cl element is detected on the surface of the Ti₄N₃Tₓ material, which corresponds to the Ti—Cl bond on the surface of Ti₄N₃Tₓ. The presence of Cl element in the nanosheets indicates that the resultant target product is an MX material (Ti₄N₃—Cl₂) containing Cl functional group. In the STEM image of the target product Ti₄N₃Tₓ (T═O) shown in FIG. 18a, the presence of a large amount of two-dimensional ultrathin nanosheets indicates that the accordion-like Ti₄N₃Tₓ can be simply peeled off to obtain the large amount of two-dimensional nanosheets. The two-dimensional nanosheets have uniform distribution of Ti, N or O elements (FIG. 18b, FIG. 18d and FIG. 18e), which indicates that the resultant target product is an MX material (Ti₄N₃—O₂) containing O functional group.

### Embodiment 7

The embodiment takes an example of using TiNbAlC as the MAX phase material and using HCl gas as the halogen hydride gas, and the hydrogen sulfide H₂S gas is used as the second gas for surface functional-group adjustment. The fabrication method is the same as that of Embodiment 6, except that the target product obtained by the reaction of TiNbAlC with HCl is TiNbC—Cl₂, the reaction is carried out at 700° C. and kept for 30 min; and then the subsequent H₂S treatment is performed and a target product TiNbC—S₂ having a surface functional group S is obtained, the reaction is carried out at 500° C. and kept for 10 min.

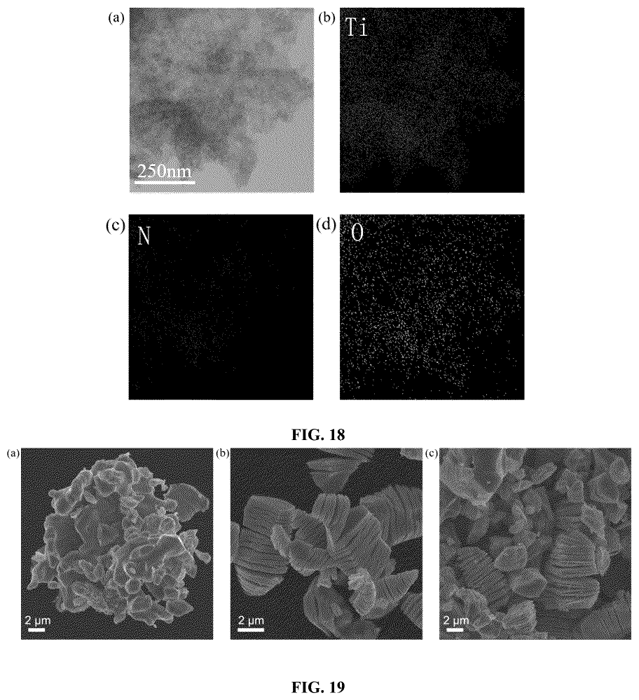

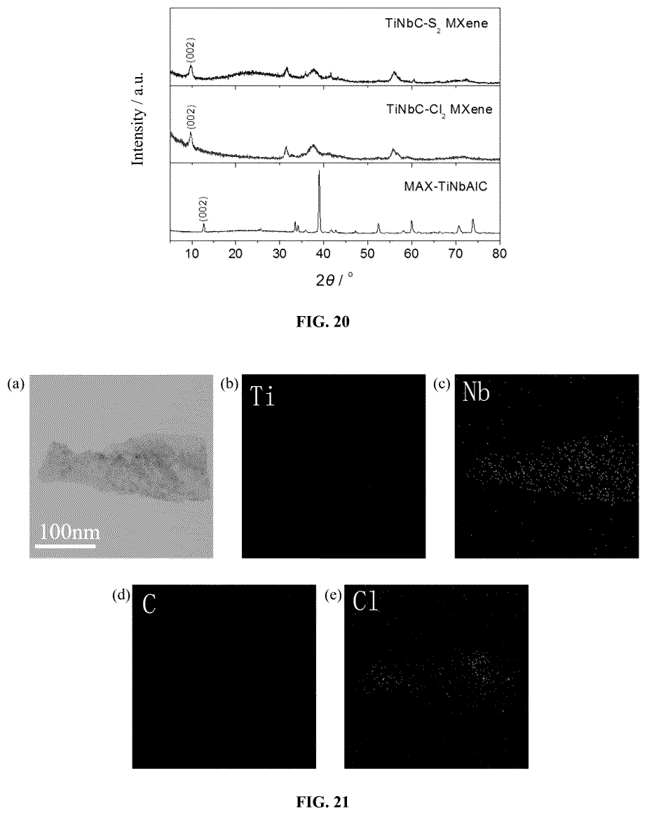

The target products are taken out after the reaction device is naturally cooled to room temperature. TiNbAlC and the two products (TiNbC—Cl₂ and TiNbC—S₂) obtained after the reaction of TiNbAlC with HCl are subject to SEM test, and the results are shown in FIG. 19a, FIG. 19b, and FIG. 19c, respectively. The target products obtained after the reaction exhibit obvious accordion-like layer structures and the accordion-like structure has obvious expansion structure stacked layer-by-layer, which is obviously different from the block morphology of the raw material TiNbAlC (FIG. 19a). TiNbAlC and the two target products are subject to XRD analysis, and the results are shown in FIG. 20. By comparison, the (002) peak of the raw material TiNbAlC appears at 12.7°, while the (002) peak of the target product obtained after the reaction with HCl and the (002) peak of the target product obtained after the subsequent H₂S treatment are both shifted to a low angle of 9.8°. It indicates that the HCl gas etches the Al element from TiNbAlC during the gas phase reaction to produce an MX material (MXene) with a sheet-like layer structure and cause the increasing of the layer interval, and the subsequent H₂S treatment doesn't change the crystal structure of TiNbC and doesn't produce a sulfide sub-phase, which is consistent with the result of the SEM photograph. In the STEM image of the target product TiNbC—Cl₂ shown in FIG. 21a, the presence of ultrathin two-dimensional nanosheets indicates that the accordion-like TiNbC—Cl₂ can be simply peeled off to obtain a large amount of two-dimensional nanosheets. The two-dimensional nanosheets have uniform distribution of Ti, Nb, C elements (FIG. 21b, FIG. 21c and FIG. 21d) and further includes Cl element (FIG. 21e), which indicates that the resultant target product is an MX material (TiNbC—Cl₂) containing Cl functional group. TiNbC—S₂ material after undergoing the treatment of H₂S gas exhibits uniform distribution of S element on the surface of TiNbC—S₂ material, as shown in FIG. 22, which indicates that the functional group on the surface of the target product can be replaced with S after undergoing the subsequent treatment, so as to obtain an MX material containing S functional group (TiNbC—S₂).

It should be noted that the reaction of adjusting the surface functional group of MX by using the gas in the embodiment is preferably carried out at a temperature ranging from 100° C. to 1000° C., more preferably, at a temperature ranging from 500° C. to 800° C. Associated with the type of the surface functional group of MX and the reaction time, the functional group with high activity is prone to react at low temperature. The optimal temperature and reaction time for the reaction of different types of MX materials carrying different functional groups are determined through limited number of experiments.

### Embodiment 8

The embodiment takes an example of using Ta₂AlC as the MAX phase material and using HI gas as the halogen hydride gas. The fabrication method is the same as that of Embodiment 3, except that the reaction temperature is set at 900° C. and kept for 20 min, and the target product obtained by the reaction of Ta₂AlC with HI is Ta₂CTₓ.

The target product is taken out after the reaction device is naturally cooled to room temperature. The target product is subject to SEM test for analysis. A large amount of expanded accordion-like structure appears in the SEM image (FIG. 23b), which is different from the block layered morphology of traditional MAX phase (FIG. 23a), indicating that the Al between Ta₂AlC layers is etched by the reaction with iodine hydride to obtain Ta₂C—I₂.

### Embodiment 9

The embodiment takes an example of using Nb₂AlC as the MAX phase material and using PH₃ gas as the gas having the etching effect, and the PH₃ gas is produced by thermal decomposition of Na₂H₂PO₂ at 200° C. to 250° C. The fabrication method is the same as that of Embodiment 3, except that the reaction temperature is set at 1500° C. and kept for 10 min, and the target product obtained by the reaction of Nb₂AlC with PH₃ gas is Nb₂CTₓ.

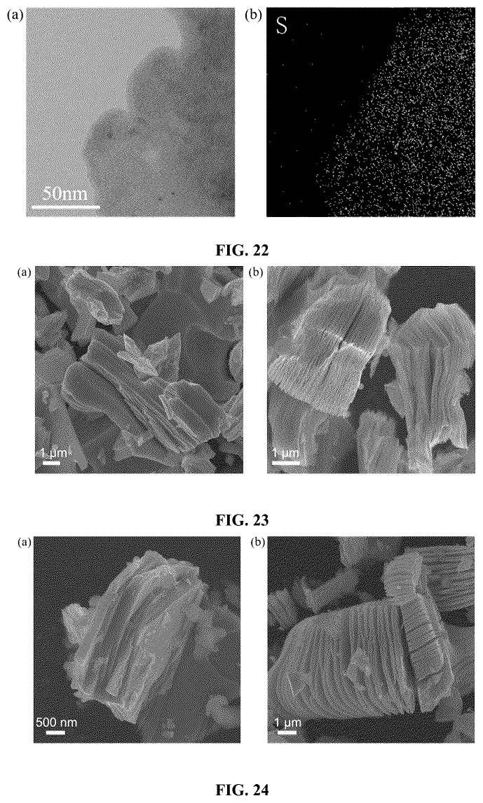

The target product is taken out after the reaction device is naturally cooled to room temperature. The target product is subject to SEM test for analysis. A large amount of expanded accordion-like structure appears in the SEM image (FIG. 24b), which is different from the block layered morphology of Nb₂AlC (FIG. 24a), indicating that the Al between Nb₂AlC layers is etched by the reaction with PH₃ to obtain Nb₂CTₓ.

### Embodiment 10

The embodiment takes an example of using Nb₂AlC as the MAX phase material and using HCl gas as the halogen hydride gas. The fabrication method is the same as that of Embodiment 3, except that the reaction temperature is set at 500° C. and kept for 2 hs, and the target product obtained by the reaction of Nb₂AlC with HCl is Nb₂CTₓ.

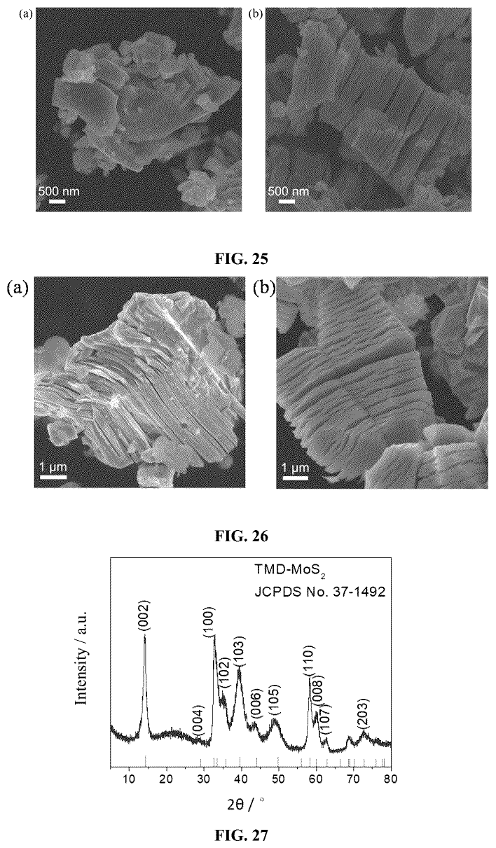

The target product is taken out after the reaction device is naturally cooled to room temperature. The target product is subject to SEM test for analysis. A large amount of expanded accordion-like structure appears in the SEM image (FIG. 25b), which is different from the block layered morphology of the MAX phase (FIG. 25a), indicating that the Al between Nb₂AlC layers is etched by the reaction with chlorine hydride to obtain Nb₂C—Cl₂.

### Embodiment 11

The embodiment takes an example of using Mo₂GeC as the MAX phase material and using elementary HCl gas as the gas having the etching effect as example. The method includes steps of:

1) placing powdery Mo₂GeC inside the reaction device 10;

2) simultaneously introducing HCl and H₂S gases at a volume ratio of 1:1 into the inside of the reaction device 10, heating the inside of the reaction device 10 to 600° C. and keeping for 40 min; the HCl gas and the Mo₂GeC undergo a gas phase etching reaction to produce Mo₂C—Cl₂, and simultaneously the produced Mo₂C—Cl₂ in turn undergoes a functional-group adjustment reaction with the H₂S gas, so that the final reaction results in an two-dimensional material Mo₂C—S₂ containing S functional group, which has a result of SEM test shown in FIG. 26a. Preferably, the embodiment may also react at 500° C. to 600° C.

### Embodiment 12

The embodiment is similar to Embodiment 11, except that the reaction temperature is controlled at 1200° C. and kept for 40 min, the HCl gas and the Mo₂GeC undergo a gas phase etching reaction to produce Mo₂C—Cl₂, and simultaneously the produced Mo₂C—Cl₂ in turn undergoes a conversion reaction with the H₂S gas to replace the C element in Mo₂C—Cl₂ with S element, so that the final reaction results in a novel two-dimensional material MoS₂. The results of SEM and XRD tests are as shown in FIG. 26b and FIG. 27. The SEM photograph shows that the product maintains the accordion-like structure stacked layer-by-layer, and the presence of the MoS₂ characteristic peaks including (002), (100), (103), (110), etc., in the XRD spectrum indicates that the product is MoS₂. Preferably, the embodiment may also react at 900° C. to 1200° C.

It can be seen from Embodiments 11 and 12 that, by adjusting the reaction temperature, the two-dimensional material Mo₂C—S₂ containing S functional group or the novel two-dimensional material MoS₂ can be obtained by one-step method, which simplifies the reaction steps.

Another creative aspect of the present disclosure relies on that, it is found that the MX-containing 2D material primarily undergoes a functional-group adjustment reaction at a relatively low reaction temperature (100° C. to 800° C.) for a reaction with a functional gas to produce an effect of adjusting the surface functional group of MX; and it primarily undergoes a conversion reaction with a functional gas at a relatively high temperature (600° C. to 1200° C.) to obtain a novel two-dimensional material. This characteristic can be seen from the comparison between Embodiment 11 and Embodiment 12, and the optimal reaction condition for the functional-group adjustment reaction or the conversion reaction with different gases can be obtained through limited number of experiments.

Still another creative aspect of the present disclosure relies on that: the MAX phase material with X being CN or N element can be etched via the gas phase etching reaction of the present disclosure. Such the MAX phase material has N element at the position of X component, so that the interaction force between the A component and the X component is enhanced. Thus, it is difficult to etch the A component by liquid phase etching in a short time (for example, more than 5 days). In the gas phase etching step of the present disclosure, the gas has stronger etching capability and can completely etch off the A component in a short time (within 30 min) to prepare the novel MX material with X being CN or N element, thereby significantly increasing the fabricating efficiency. This characteristic can be seen from Embodiments 4 and 6, and the optimal reaction conditions for the etching reaction of different MAX materials with the gas can be obtained through limited numbered of experiments.

### Embodiment 13

The embodiment takes an example of using Ti₃AlC₂ as the MAX phase material, using HCl gas as the halogen hydride gas, and using hydrogen sulfide H₂S gas as the second gas for surface functional-group adjustment, and the fabrication method includes:
1) placing Ti₃AlC₂ into a high-temperature reaction furnace, introducing the HCl gas into the high-temperature reaction furnace, heating at a rate of 5° C./min to 700° C. and keeping for 30 min, to obtained a target product Ti₃C₂—Cl₂;
2) introducing the H₂S gas into the high-temperature reaction furnace, heating at 700° C. and keeping for 10 min, to obtain a target product Ti₃C₂—S₂ having the surface functional group S; taking out the target product after the reaction device is naturally cooled to room temperature.

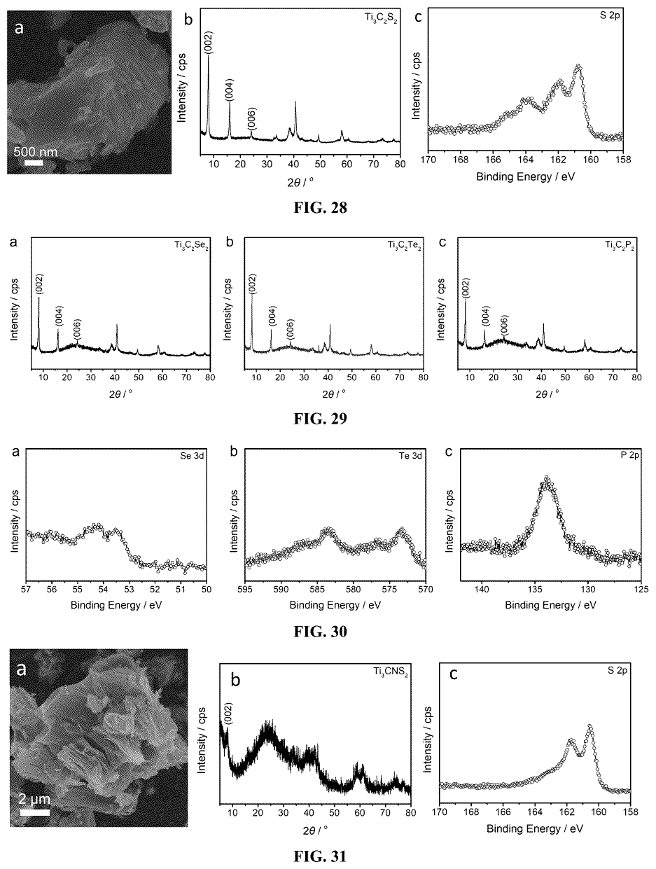

The target product obtained after Ti₃AlC₂ reacts with hydrogen chloride and hydrogen sulfide is subject to SEM test, and the result is shown in FIG. 28a. The target product obtained after the reaction exhibits an obvious accordion-like layer structure, which have an obvious expansion structure stacked layer-by-layer. The target product with such accordion-like structure is subject to XRD analysis, and the result is shown in FIG. 28b. By comparison, the (002) peak of the target product after the reaction with hydrogen chloride and hydrogen sulfide is shifted to a low angle of 8.0°, indicating that the H₂S treatment doesn't change the crystalline structure of the MX material (MXene) with a sheet-like layer structure, and doesn't produce a sulfide sub-phase. Ti₃C₂Tₓ obtained after the reaction of Ti₃AlC₂ with HCl and H₂S is characterized by X-ray photoelectron spectrometer (XPS) for its surface functional group. As shown in FIG. 28c, an obvious signal of S element is detected on the surface of Ti₃C₂Tₓ material, which corresponds to the Ti—S bond on the surface of Ti₃C₂Tₓ. The presence of S element in the nanosheets indicates that the resultant target product is an MX material (Ti₃C₂—S₂) containing S functional group.

### Embodiment 14

The embodiment takes an example of using Ti₃AlC₂ as the MAX phase material, using HCl gas as the halogen hydride gas, Se powder, Te powder, or P powder is used as the second reaction substance for surface functional-group adjustment, the fabrication method includes:
1) placing Ti₃AlC₂ into a high-temperature reaction furnace, introducing the HCl gas into the high-temperature reaction furnace, heating at a rate of 5° C./min to 700° C. and keeping for 30 min, to obtain a target product Ti₃C₂—Cl₂;
2) heating Se powder to produce Se vapor by sublimation, which is in turn introduced into the high-temperature reaction furnace, heating to 700° C. and keeping for 10 min, and taking out the product Ti₃C₂—Se₂ after the reaction device is naturally cooled to room temperature.

Using the same method, the Se powder were replaced with Te powder or P powder to obtain the products Ti₃C₂—Te₂ and Ti₃C₂—P₂, respectively.

The product is taken out and subject to XRD test, and the result is shown in FIG. 29. The (002) peak of the target product is shifted to a low angle of 8.1°, which corresponds to the (002) peak of MXene Ti₃C₂, indicating that the Se, Te or P treatment doesn't change the crystalline structure of the MX material (MXene) with a sheet-like layer structure, and doesn't generate a sub-phase. Ti₃C₂Tₓ obtained by the reaction of Ti₃AlC₂ with HCl and Se, Te, or P is characterized by X-ray photoelectron spectrometer (XPS) for its surface functional group. As shown in FIG. 30, an obvious signal of Se, Te, or P element is detected on the surface of Ti₃C₂Tₓ material, which corresponds to the Ti—Se, Ti—Te, or Ti—P bonds on the surface of Ti₃C₂Tₓ, respectively. The presence of Se, Te, or P element in such nanosheets indicates that the resultant target product is an MX material (Ti₃C₂—Se₂, Ti₃C₂—Te₂ or Ti₃C₂—P₂) containing Se, Te, or P functional group.

### Embodiment 15

The embodiment takes an example of using Ti₃AlCN as the MAX phase material, using HCl gas as the halogen hydride gas, and hydrogen sulfide H₂S gas is used as the second gas for surface functional-group adjustment. The fabrication method is similar to that of Embodiment 13, except that the target product obtained by the reaction of Ti₃AlCN with HCl is Ti₃CN—Cl₂, the reaction is carried out at 650° C. and kept for 30 min; and then the H₂S gas is introduced into the high-temperature reaction furnace for treatment, the reaction is carried out at 650° C. and kept for 10 min, to obtain the target product Ti₃CN—S₂ containing the surface functional group S.

The target product is taken out after the reaction device is naturally cooled to room temperature. The target product obtained after the reaction of Ti₃AlCN with hydrogen chloride and hydrogen sulfide is subject to SEM test, and the result is shown in FIG. 31a. The target product obtained after the reaction exhibits an obvious accordion-like layer structure, which has an expansion structure stacked layer-by-layer. The target product with such accordion-like structure is subject to XRD analysis, and the result is as shown in FIG. 31b. By comparison, the (002) peak of the target product after the reaction with hydrogen sulfide is shifted to a low angle of 7.9°, indicating that the H₂S treatment doesn't change the crystalline structure of the MX material (MXene) with a sheet-like layer structure, and doesn't produce a sulfide sub-phase. Ti₃CNTₓ obtained after the reaction of Ti₃AlCN with HCl and H₂S is characterized by X-ray photoelectron spectrometer (XPS) for its surface functional group. As shown in FIG. 31c, an obvious signal of S element is detected on the surface of Ti₃CNTₓ material, which corresponds to the Ti—S bond on the surface of Ti₃CNTₓ. The presence of S element in the nanosheets indicates that the resultant target product is an MX material (Ti₃CN—S₂) containing S functional group.

### Embodiment 16

The embodiment takes an example of using Ti₃AlCN as the MAX phase material, using HCl gas as the halogen hydride gas, Se powder, Te powder or P powder is used as the second reaction substance for surface functional-group adjustment. The fabrication method is similar to that of Embodiment 14, except that the target product obtained by the reaction of Ti₃AlCN with HCl is Ti₃CN—Cl₂, the reaction is carried out at 650° C. and kept for 30 min, and the subsequent Se, Te, or P treatment results in a target product Ti₃CN—Se₂, Ti₃CN—Te₂ or Ti₃CN—P₂ in which the surface functional group is Se, Te, or P, respectively; and the reaction is carried out at 650° C. and kept for 10 min.

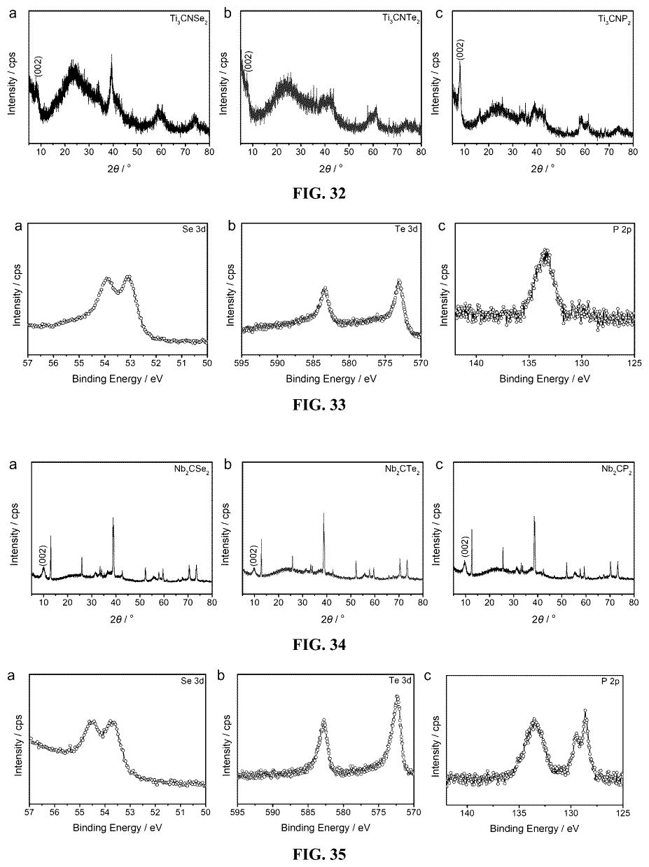

After the reaction device is naturally cooled to room temperature, the target product is taken out and analyzed by XRD test, and the results are shown in FIG. 32. The (002) peak of the target product is shifted to a low angle of 7.8°, which corresponds to the (002) peak of the MXene Ti₃CN, indicating that the Se, Te, or P treatment doesn't change the crystalline structure of the MX material (MXene) with a sheet-like layer structure, and doesn't generate a sub-phase. Ti₃CNTₓ obtained after the reaction of Ti₃AlCN with HCl and Se, Te, or P is characterized by X-ray photoelectron spectrometer (XPS) for its surface functional group. As shown in FIG. 33, an obvious signal of Se, Te, or P element is detected on the surface of Ti₃CNTₓ material, which corresponds to the Ti—Se, Ti—Te, or Ti—P bond on the surface of Ti₃CNTₓ. The presence of Se, Te, or P element in the nanosheets indicates that the resultant target product is an MX material (Ti₃CN—Se₂, Ti₃CN—Te₂, or Ti₃CN—P₂) containing Se, Te, or P functional group.

### Embodiment 17

The embodiment takes an example of using Nb₂AlC as the MAX phase material, using HCl gas as the halogen hydride gas, and Se powder, Te powder or P powder is used as the second reaction substance for surface functional-group adjustment. The fabrication method is similar to that of Embodiment 14, except that the target product obtained by the reaction of Nb₂AlC with HCl is Nb₂C—Cl₂, the reaction is carried out at 700° C. and kept for 30 min; and the subsequent Se, Te, or P treatment results in a target product Nb₂C—Se₂, Nb₂C—Te₂ or Nb₂C—P₂ in which the surface functional group is Se, Te or P, respectively, and the reaction is carried out at 700° C. and kept for 10 min.

After the reaction device is naturally cooled to room temperature, the target product is taken out and tested by XRD analysis, and the results are shown in FIG. 34. The (002) peak of the target product is shifted to a low angle of 10°, which corresponds to the (002) peak of MXene Nb₂C, indicating that the Se, Te or P treatment doesn't change the crystalline structure of the MX material (MXene) with a sheet-like layer structure, and doesn't generate a sub-phase. The Nb₂CTₓ obtained after the reaction of Nb₂AlC with HCl and Se, Te, or P is characterized by X-ray photoelectron spectrometer (XPS) for its surface functional group. As shown in FIG. 35, an obvious signal of Se, Te, or P element is detected on the surface of Nb₂CTₓ material, which corresponds to the Ti—Se, Ti—Te, or Ti—P bond on the surface of Nb₂CTₓ. The presence of Se, Te, or P element in the nanosheets indicates that the resultant target product is an MX material (Nb₂C—Se₂, Nb₂C—Te₂, or Nb₂C—P₂) containing Se, Te, or P functional group.

### Embodiment 18

The embodiment takes an example of using Nb₄AlC₃ as the MAX phase material and using HCl gas as the halogen hydride gas. The fabrication method is the same as that of Embodiment 3, except that the reaction temperature is set at 800° C. and kept for 30 min, and the target product obtained by the reaction of Nb₄AlC₃ with HCl is Nb₄C₃Tₓ.

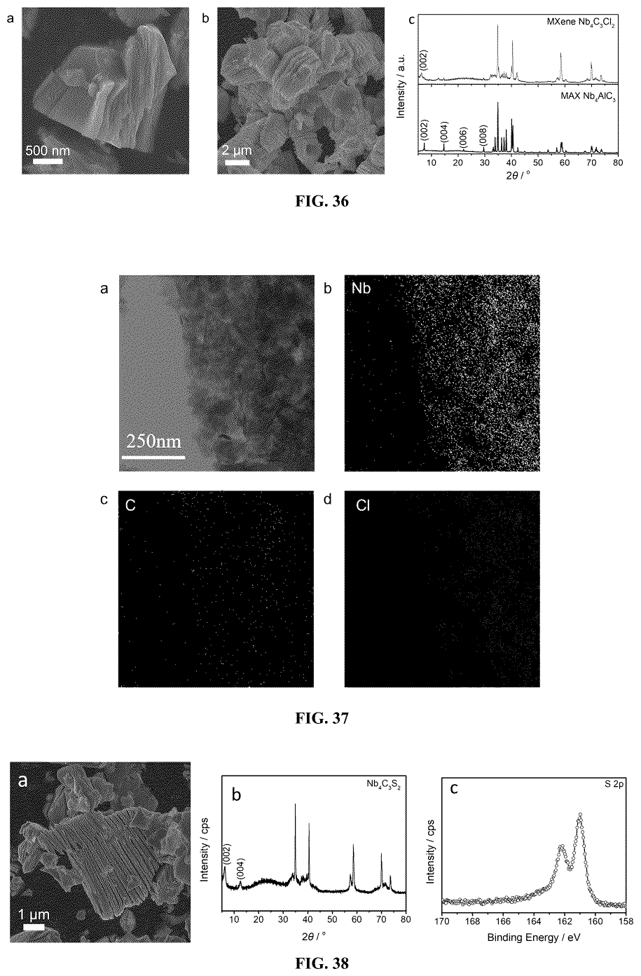

The MAX phase material Nb₄AlC₃ and the target product are subject to scanning electron microscope (SEM) test, respectively, and the results are shown in FIG. 36a and FIG. 36b. By comparison, it can be seen that the morphology of Nb₄AlC₃ is a three-dimensional block structure, while the target product exhibits an accordion-like layer structure. The MAX phase material Nb₄AlC₃ and the target product are subject to X-ray diffraction (XRD) analysis, and the results are shown in FIG. 36c. By comparison, the (002) peak of the raw material Nb₄AlC₃ appears at 7.4°, while the (002) peak of the target product obtained after the reaction with the HCl gas is shifted to a low angle of 6.4°. It indicates that the HCl gas etches the Al element from the Nb₄AlC₃ during the gas phase etching reaction to produce an MX material (MXene) with a layer structure and cause the increasing of the layer interval, which is consistent with the result of the SEM photograph of Nb₄C₃Tₓ. The scanning transmission electron microscope (STEM) image of the transmission electron microscope (TEM) of the target product Nb₄C₃Tₓ is as shown in FIG. 37a, in which the presence of a large amount of two-dimensional ultrathin nanosheets indicates that the accordion-like Nb₄C₂Tₓ can be simply peeled off to obtain two-dimensional nanosheets, the two-dimensional nanosheets have uniform distribution of Nb and C elements (FIG. 37b and FIG. 37c) and further includes Cl element (FIG. 37d), indicating that the resultant target product is an MX material (Nb₄C₃—Cl₂) containing Cl functional group.

### Embodiment 19

The embodiment takes an example of using Nb₄AlC₃ as the MAX phase material, using HCl gas as the halogen hydride gas, and using hydrogen sulfide H₂S gas as the second gas for surface functional-group adjustment. The fabrication method is similar with that of Embodiment 13, except that the target product obtained by the reaction of Nb₄AlC₃ with HCl is Nb₄C₃—Cl₂, the reaction is carried out at 800° C. and kept for 30 min; the subsequent H₂S treatment results in a target product Nb₄C₃—S₂ in which the surface functional group is S, and the reaction is carried out at 700° C. and kept for 10 min.

The target product is taken out after the reaction device is naturally cooled to room temperature. The target product obtained by the reaction of Nb₄AlC₃ with hydrogen chloride and hydrogen sulfide is subject to SEM test and the result is shown in FIG. 38a. The target product obtained after the reaction exhibits an obvious accordion-like layer structure, which has an obvious expansion structure stacked layer-by-layer. The target product with such accordion-like structure is subject to XRD analysis, and the result is as shown in FIG. 38b. By comparison, the (002) peak of the target product after the reaction with hydrogen sulfide is shifted to a low angle of 6.2°, indicating that the H₂S treatment doesn't change the crystalline structure of the MX material (MXene) with a sheet-like layer structure, and doesn't produce a sulfide sub-phase. Nb₄C₃Tₓ obtained by the reaction of Nb₄AlC₃ with HCl and H₂S is characterized by X-ray photoelectron spectrometer (XPS) for its surface functional group. As shown in FIG. 38c, an obvious signal of S element is detected on the surface of Nb₄C₃Tₓ material, which corresponds to the Nb—S bond on the surface of Nb₄C₃Tₓ. The presence of S element in these nanosheets indicates that the resultant target product is an MX material (Ti₄C₂—S₂) containing S functional group.

### Embodiment 20

The embodiment takes an example of using Nb₄AlC₃ as the MAX phase material, using HCl gas as the halogen hydride gas, and using Se powder, Te powder or P powder as the second reaction substance as the second gas for surface functional-group adjustment. The fabrication method is similar to that of Embodiment 14, except that the target product obtained by the reaction of Nb₄AlC₃ with HCl is Nb₄C₃—Cl₂, the reaction is carried out at 800° C. and kept for 30 min; and the subsequent Se, Te, or P treatment results in a target product Nb₄C₃—Se₂, Nb₄C₃—Te₂ or Nb₄C₃—P₂ in which the surface functional group is Se, Te or P, respectively, and the reaction is carried out at 700° C. and kept for 10 min.

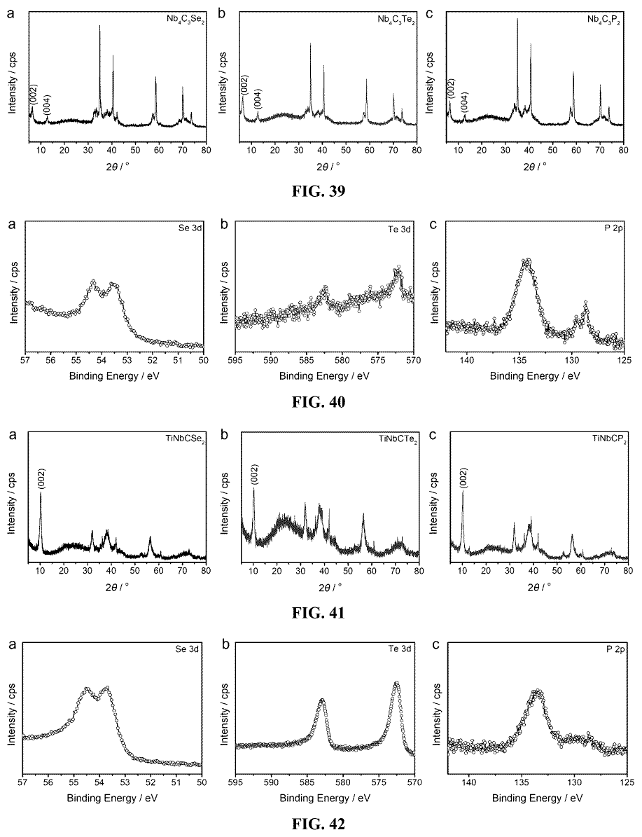

After the reaction device is naturally cooled to room temperature, the target product is taken out and subject to XRD analysis, and the result is shown in FIG. 39. The (002) peak of the target product is located at 6.4°, which corresponds to the (002) peak of MXene Nb₄C₃, indicating that the Se, Te or P treatment doesn't change the crystalline structure of the MX material (MXene) with a sheet-like layer structure, and doesn't generate a sub-phase. The Nb₄C₃Tₓ obtained by the reaction of Nb₄AlC₃ with HCl and Se, Te, or P is characterized by X-ray photoelectron spectrometer (XPS) for its surface functional group. As shown in FIG. 40, an obvious signal of Se, Te, or P element is detected on the surface of Ti₄C₂Tₓ material, which corresponds to the Ti—Se, Ti—Te, or Ti—P bond on the surface of Ti₄C₂Tₓ, respectively. The presence of Se, Te, or P element in the nanosheets indicates that the resultant target product is an MX material (Ti₄C₂—Se₂, Ti₄C₂—Te₂ or Ti₄C₂—P₂) containing Se, Te, or P functional group.

### Embodiment 21

The embodiment takes an example of using TiNbAlC as the MAX phase material, using HCl gas as the halogen hydride gas, and using Se powder, Te powder or P powder as the second reaction substance as the second gas for surface functional-group adjustment. The fabrication method is similar to that of Embodiment 14, except that the target product obtained by the reaction of TiNbAlC with HCl is TiNbC—Cl₂, the reaction is carried out at 700° C. and kept for 30 min; the subsequent Se, Te, or P treatment results in a target product TiNbC—Se₂, TiNbC—Te₂ or TiNbC—P₂ in which the surface functional group is Se, Te, or P, respectively, and the reaction is carried out at 700° C. and kept for 10 min.

After the reaction device is naturally cooled to room temperature, the target product is taken out and tested by XRD analysis, and the result is shown in FIG. 41. The (002) peak of the target product is shifted to a low angle of 9.8°, which corresponds to the (002) peak of MXene TiNbC, indicating that the Se, Te or P treatment doesn't change the crystalline structure of the MX material (MXene) with a sheet-like layer structure, and doesn't generate a sub-phase. TiNbCTₓ obtained after the reaction of TiNbAlC with HCl and Se, Te, or P is characterized by X-ray photoelectron spectrometer (XPS) for its surface functional group. As shown in FIG. 42, an obvious signal of Se, Te, or P element is detected on the surface of Nb₂CTₓ material, which corresponds to the Ti—Se/Nb—Se, Ti—Te/Nb—Te, and Ti—P/Nb—P bond on the surface of TiNbCTₓ. The presence of Se, Te, or P element in the nanosheets indicates that the resultant target product is an MX material (TiNbC—Se₂, TiNbC—Te₂ or TiNbC—P₂) containing Se, Te, or P functional group.

### Embodiment 22

The embodiment takes an example of using Ta₂AlC as the MAX phase material, using HCl gas as the halogen hydride gas, and using hydrogen sulfide H₂S gas as the second gas for surface functional-group adjustment. The fabrication method is similar to that of Embodiment 13, except that the target product obtained by the reaction of Ta₂AlC with HCl is Ta₂C—Cl₂, the reaction is carried out at 800° C. and kept for 30 min; the subsequent H₂S treatment results in a target product Ta₂C—S₂ in which the surface functional group is S, and the reaction is carried out at 700° C. and kept for 10 min.

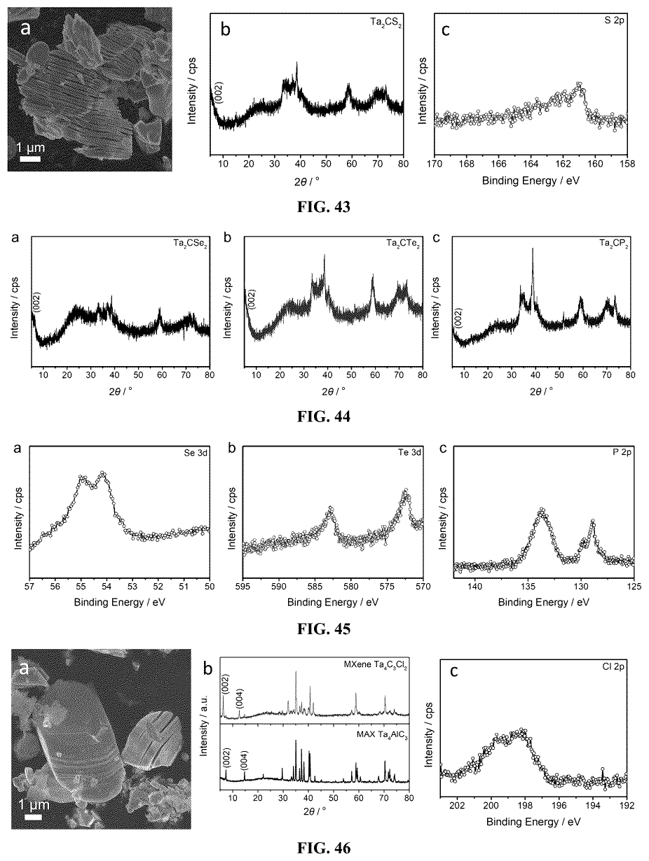

The target product is taken out after the reaction device is naturally cooled to room temperature. The target product Ta₂C—S₂ after reaction of Ta₂AlC with hydrogen chloride and hydrogen sulfide is subject to SEM test, and the result is shown in FIG. 43a. The target product obtained after the reaction exhibits an obvious accordion-like layer structure, which has an obvious expansion structure stacked layer-by-layer. The target product with such accordion-like structure is subject to XRD analysis, and the results are shown in FIG. 43b. By comparison, the (002) peak of the target product after reaction with hydrogen chloride and hydrogen sulfide is shifted to a low angle of 7.4°, indicating that the H₂S treatment doesn't change the crystal structure of the MX material (MXene) with a sheet-like layer structure, and doesn't produce a sulfide sub-phase. Ta₂CTₓ obtained after the reaction of Ta₂AlC with HCl and H₂S is characterized by X-ray photoelectron spectrometer (XPS) for its surface functional group. As shown in FIG. 43c, an obvious signal of S element is detected on the surface of Ta₂CTₓ material, which corresponds to the Ta—S bond on the surface of Ta₂CTₓ. The presence of S element in the nanosheets indicates that the resultant target product is an MX material (Ta₂C—S₂) containing S functional group.

### Embodiment 23

The embodiment takes an example of using Ta₂AlC as the MAX phase material, using HCl gas as the halogen hydride gas, and using Se powder, Te powder or P powder as the second reaction substance as the second gas for surface functional-group adjustment. The fabrication method is similar to that of Embodiment 14, except that the target product obtained by the reaction of Ta₂AlC with HCl is Ta₂C—Cl₂, the reaction is carried out at 800° C. and kept for 30 min; and the subsequent Se, Te, or P treatment results in a target product Ta₂C—Se₂, Ta₂C—Te₂ and Ta₂C—P₂ in which the surface functional group is Se, Te or P, respectively, and the reaction is carried out at 700° C. and kept for 10 min.

After the reaction device is naturally cooled to room temperature, the target product is taken out and tested by XRD analysis, and the result is shown in FIG. 44. The (002) peak of the target product is shifted to a low angle of 6.3°, which corresponds to the (002) peak of MXene Ta₂Cₓ indicating that the Se, Te or P treatment doesn't change the crystalline structure of the MX material (MXene) with a sheet-like layer structure, and doesn't generate a sub-phase. Ta₂CTₓ obtained after the reaction of Ta₂AlC with HCl and Se, Te, or P is characterized by X-ray photoelectron spectrometer (XPS) for its surface functional group. As shown in FIG. 45, an obvious signal of Se, Te, or P element is detected on the surface of Ta₂CTₓ material, which corresponds to the Ta—Se, Ta—Te, or Ta—P bond on the surface of Ta₂CTₓ. The presence of Se, Te, or P element in the nanosheets indicates that the resultant target product is an MX material (Ta₂C—Se₂, Ta₂C—Te₂ and Ta₂C—P₂) containing Se, Te, or P functional group.

### Embodiment 24

The embodiment takes an example of using Ta₄AlC₃ as the MAX phase material, and using HCl gas as the halogen hydride gas. The fabrication method is similar to that of Embodiment 3, except that the reaction temperature is set at 800° C. and kept for 30 min, and the target product obtained by the reaction of Ta₄AlC₃ with HCl is Ta₄C₃Tₓ.

The MAX phase material Ta₄AlC₃ and the target product are subject to scanning electron microscope (SEM) test, respectively, and the results are shown in FIG. 46a. The target product exhibits an obvious accordion-like layer structure which is different from the block structure of the traditional MAX phase. The MAX phase material Ta₄AlC₃ and the target product are subject to X-ray diffraction (XRD) analysis, and the results are shown in FIG. 46b. By comparison, the (002) peak of the raw material Ta₄AlC₃ appears at 7.4°, while the (002) peak of the target product obtained after reaction with HCl is shifted to a low angle of 6.3°. It indicates that the HCl gas etches the Al element from Ta₄AlC₃ during the gas phase etching reaction to produce an MX material (MXene) with a sheet-like layer structure and cause the increasing of the layer interval, which is consistent with the result of the SEM photograph of Ta₄C₃Tₓ. The surface functional group of Ta₄C₃Tₓ obtained by the reaction of Ta₄AlC₃ with HCl is characterized by X-ray photoelectron spectrometer (XPS). As shown in FIG. 46c, an obvious signal of Cl element is detected on the surface of the Ta₄C₃Tₓ material, which corresponds to the Ta—Cl bond on the surface of Ta₄C₃Tₓ. The presence of Cl element in the nanosheets indicates that the resultant target product is an MX material (Ta₂C—Cl₂) containing Cl functional group.

### Embodiment 25

The embodiment takes an example of using Ta₄AlC₃ as the MAX phase material, using HCl gas as the halogen hydride gas, and using hydrogen sulfide H₂S gas as the second gas for surface functional-group adjustment. The fabrication method is similar to that of Embodiment 13, except that the target product obtained by the reaction of Ta₄AlC₃ with HCl is Ta₄C₃—Cl₂, the reaction is carried out at 800° C. and kept for 30 min; the subsequent H₂S treatment results in a target product Ta₄C₃—S₂ in which the surface functional group is S, and the reaction is carried out at 700° C. and kept for 10 min.

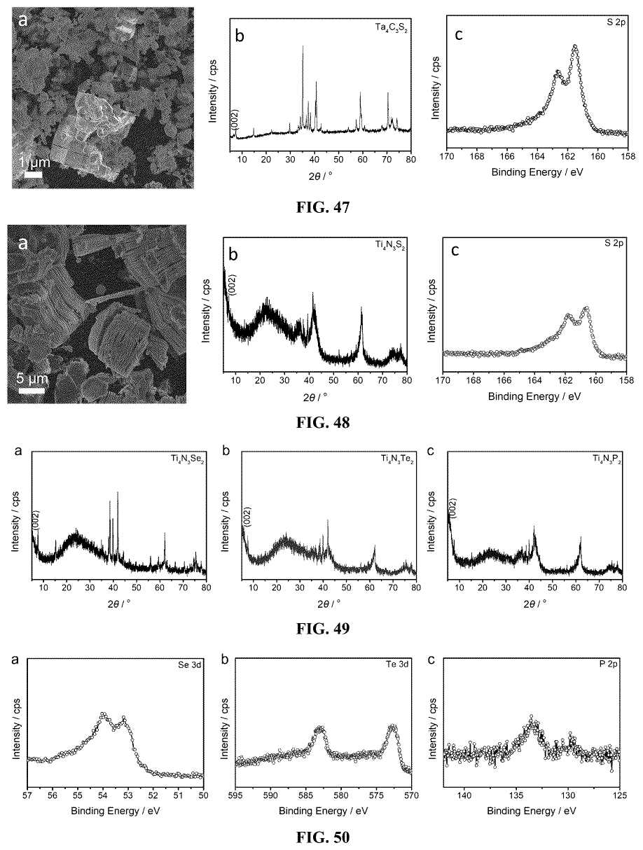

The target product is taken out after the reaction device is naturally cooled to room temperature. The target product obtained after the reaction of Ta₄AlC₃ with HCl and hydrogen sulfide is subject to SEM test, and the result is shown in FIG. 47a. The target product obtained after the reaction exhibits an obvious accordion-like layer structure, which has an obvious expansion structure stacked layer-by-layer. The target product with such accordion-like structure is subject to XRD analysis, and the result is shown in FIG. 47b. By comparison, the (002) peak of the target product after reaction with HCl and hydrogen sulfide is shifted to a low angle of 6.5°, indicating that the H₂S treatment doesn't change the crystal structure of the MX material (MXene) with a sheet-like layer structure, and doesn't produce a sulfide sub-phase. Ta₄C₃Tₓ obtained after the reaction of Ta₄AlC with HCl and H₂S is characterized by X-ray photoelectron spectrometer (XPS) for its surface functional group. As shown in FIG. 47c, an obvious signal of S element is detected on the surface of Ta₄C₃Tₓ material, which corresponds to the Ta—S bond on the surface of Ta₄C₃Tₓ. The presence of S element in the nanosheets indicates that the resultant target product is an MX material (Ta₄C₃—S₂) S containing functional group S.

### Embodiment 26

The embodiment takes an example of using Ti₄AlN₃ as the MAX phase material, using HCl gas as the halogen hydride gas, and using hydrogen sulfide H₂S gas as the second gas for surface functional-group adjustment. The fabrication method is similar to that of Embodiment 13, except that the target product obtained by the reaction of Ti₄AlN₃ with HCl is Ti₄N₃—Cl₂, the reaction is carried out at 650° C. and kept for 30 min; the subsequent H₂S treatment results in a target product Ti₄N₃—S₂ in which the surface functional group is S, and the reaction is carried out at 650° C. and kept for 10 min.

The target product is taken out after the reaction device is naturally cooled to room temperature. The target product obtained after the reaction of Ti₄AlN₃ with HCl and hydrogen sulfide is subject to SEM test, and the result is shown in FIG. 48a. The target product obtained after the reaction exhibits an obvious accordion-like layer structure, which has an obvious expansion structure stacked layer-by-layer. The target product with such accordion-like structure is subject to XRD analysis, and the result is shown in FIG. 48b. By comparison, the (002) peak of the target product after reaction with HCl and hydrogen sulfide is shifted to a low angle of 5.7°, indicating that the H₂S treatment doesn't change the crystal structure of the MX material (MXene) with a sheet-like layer structure, and doesn't produce a sulfide sub-phase. Ti₄N₃Tₓ obtained after the reaction of Ti₄AlN₃ with HCl and H₂S is characterized by X-ray photoelectron spectrometer (XPS) for its surface functional group. As shown in FIG. 48c, an obvious signal of S element is detected on the surface of Ti₄N₃Tₓ material, which corresponds to the Ti—S bond on the surface of Ti₄N₃Tₓ. The presence of S element in the nanosheets indicates that the resultant target product is an MX material (Ti₄N₃—S₂) containing functional group S.

### Embodiment 27

The embodiment takes an example of using Ti₄AlN₃ as the MAX phase material, using HCl gas as the halogen hydride gas, and using Se powder, Te powder or P powder as the second reaction substance for surface functional-group adjustment. The fabrication method is similar to that of Embodiment 14, except that the target product obtained by the reaction of Ti₄AlN₃ with HCl is Ti₄N₃—Cl₂, the reaction is carried out at 650° C. and kept for 30 min; and the subsequent Se, Te, or P treatment results in a target product Ti₄N₃—Se₂, Ti₄N₃—Te₂ or Ti₄N₃—P₂ in which the surface functional group is Se, Te or P, respectively, and the reaction is carried out at 650° C. and kept for 10 min.

After the reaction device is naturally cooled to room temperature, the target product is taken out and tested by XRD analyzed and the result is shown in FIG. 49. The (002) peak of the target product is shifted to a low angle of 5.8°, which corresponds to the (002) peak of MXene Ti₄N₃, indicating that Se, Te or P treatment doesn't change the crystalline structure of the MX material (MXene) with a sheet-like layer structure, and doesn't generate a sub-phase. Ti₄N₃Tₓ obtained by the reaction of Ti₄AlN₃ with HCl and Se, Te, or P is characterized by X-ray photoelectron spectrometer (XPS) for its surface functional group. As shown in FIG. 50, an obvious signal of Se, Te, or P element is detected on the surface of Ti₄N₃Tₓ material, which corresponds to the Ti—Se, Ti—Te, or Ti—P bonds on the surface of Ti₄N₃Tₓ, respectively. The presence of Se, Te, or P element in such nanosheets indicates that the resultant target product is an MX material (Ti₄N₃—Se₂, Ti₄N₃—Te₂ and Ti₄N₃—P₂) containing Se, Te, or P functional group.

### Embodiment 28

The embodiment takes an example of using Ti₂AlC as the MAX phase material, and using HCl gas as the halogen hydride gas. The fabrication method is similar to that of Embodiment 3, except that the reaction temperature is set at 700° C. and kept for 20 min, and the target product obtained by the reaction of Ti₂AlC with HCl is Ti₂CTₓ.

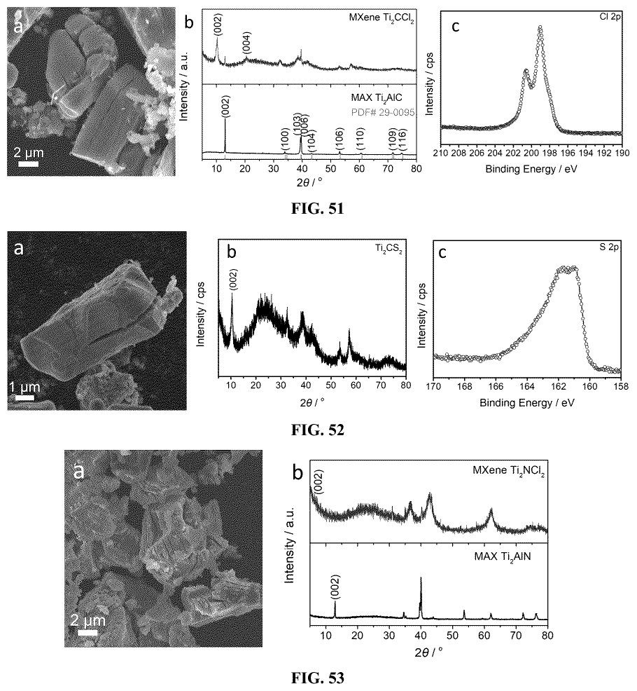

The target product is subject to scanning electron microscope (SEM) test, and the result is shown in FIG. 51a. By comparison, it can be seen that the target product exhibits an obvious accordion-like layer structure. The MAX phase material Ti₂AlC and the target product are subject to X-ray diffraction (XRD) analysis, and the results are shown in FIG. 51b. By comparison, the (002) peak of the raw material Ti₂AlC appears at 13.0°, while the (002) peak of the target product obtained after reaction with HCl is shifted to a low angle of 10.4°. It indicates that the HCl gas etches the Al element from Ti₂AlC during the gas phase etching reaction to produce an MX material (MXene) with a sheet-like layer structure and cause the increasing of the layer interval, which is consistent with the result of the SEM photograph of Ti₂CTₓ. Ti₂CTₓ obtained after the reaction of Ti₂AlC with HCl is characterized by X-ray photoelectron spectrometer (XPS) for its surface functional group. As shown in FIG. 51c, an obvious signal of Cl element is detected on the surface of Ti₂CT x material, which corresponds to the Ti—Cl bond on the surface of Ti₂CTₓ. The presence of Cl element in the nanosheets indicates that the resultant target product is an MX material (Ti₂C—Cl₂) containing Cl functional group.

### Embodiment 29

The embodiment takes an example of using Ti₂AlC as the MAX phase material, using HCl gas as the halogen hydride gas, and using hydrogen sulfide H₂S gas as the second gas for surface functional-group adjustment. The fabrication method is similar to that of Embodiment 13, except that the target product obtained by the reaction of Ta₂AlC with HCl is Ti₂C—Cl₂, the reaction is carried out at 700° C. and kept for 20 min; the subsequent H₂S treatment results in a target product Ti₂C—S₂ in which the surface functional group is S, and the reaction is carried out at 700° C. and kept for 10 min.

The target product is taken out after the reaction device is naturally cooled to room temperature. The target product obtained after the reaction of Ti₂AlC with hydrogen chloride and hydrogen sulfide is subject to SEM test, and the result is shown in FIG. 52a. The target product obtained after the reaction exhibits an obvious accordion-like layer structure, which has an obvious expansion structure stacked layer-by-layer. The target product with such accordion-like structure is subject to XRD analysis, and the result is shown in FIG. 52b. By comparison, the (002) peak of the target product after reaction with HCl and hydrogen sulfide is shifted to a low angle of 9.8°, indicating that the H₂S treatment doesn't change the crystal structure of the MX material (MXene) with a sheet-like layer structure, and doesn't produce a sulfide sub-phase. Ti₂CTₓ obtained after the reaction of Ti₂AlC with HCl and H₂S is characterized by X-ray photoelectron spectrometer (XPS) for its surface functional group. As shown in FIG. 52c, an obvious signal of S element is detected on the surface of Ti₂CTₓ material, which corresponds to the Ti—S bond on the surface of Ti₂CTₓ. The presence of S element in the nanosheets indicates that the resultant target product is an MX material (Ti₂C—S₂) containing functional group S.

### Embodiment 30

The embodiment takes an example of using Ti₂AlN as the MAX phase material, and using HCl gas as the halogen hydride gas. The fabrication method is similar to that of Embodiment 3, except that the reaction temperature is set at 700° C. and kept for 20 min, and the target product obtained by the reaction of Ti₂AlNC with HCl is Ti₂NCTₓ.

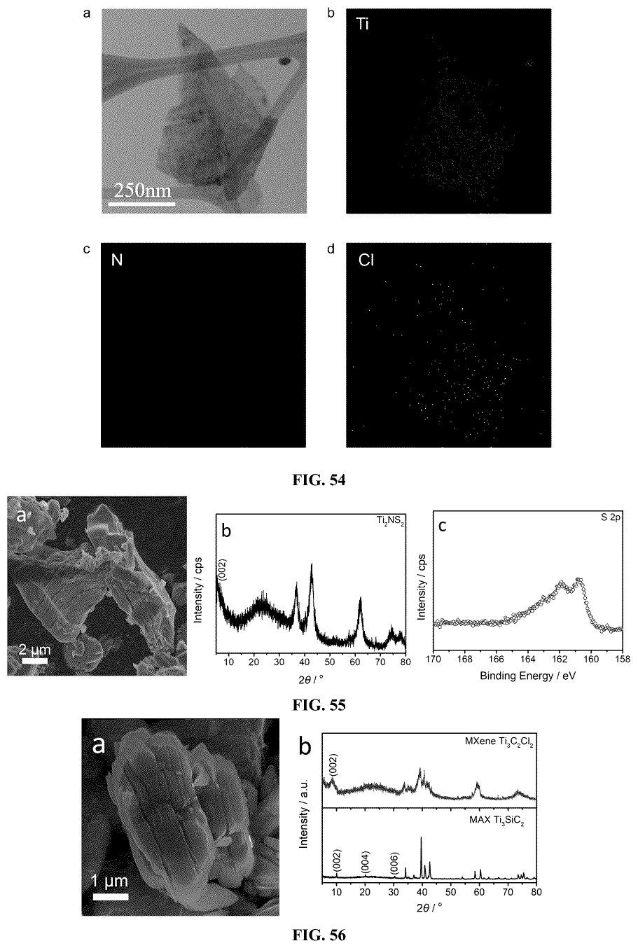

The target product is subject to scanning electron microscope (SEM) test, and the result is shown in FIG. 53a. The target product exhibits an obvious accordion-like layer structure. The MAX phase material Ti₂AlN and the target product are subject to X-ray diffraction (XRD) analysis, and the results are shown in FIG. 53b. By comparison, the (002) peak of the raw material Ti₂AlN appears at 13.0°, while the (002) peak of the target product obtained after reaction with HCl is shifted to a low angle of 7.4°. It indicates that the HCl gas etches the Al element from Ti₂AlN during the gas phase etching reaction to produce an MX material (MXene) with a sheet-like layer structure and cause the increasing of the layer interval, which is consistent with the result of the SEM photograph of Ti₂NTₓ. The scanning transmission electron microscope (STEM) graph of the transmission electron microscope (TEM) of the target product Ti₂NTₓ is as shown in FIG. 54a, in which the presence of a large amount of two-dimensional ultrathin nanosheets indicates that the accordion-like Ti₂NTₓ can be simply peeled off to obtain two-dimensional nanosheets, the two-dimensional nanosheets have uniform distribution of Ti and N elements (FIG. 54b and FIG. 54c), and the presence of Cl element in the nanosheets (FIG. 54d) indicates that the resultant target product is an MX material (Ti₂N—Cl₂) containing Cl functional group.

### Embodiment 31

The embodiment takes an example of using Ti₂AlN as the MAX phase material, using HCl gas as the halogen hydride gas, and using hydrogen sulfide H₂S gas as the second gas for surface functional-group adjustment. The fabrication method is similar to that of Embodiment 13, except that the target product obtained by the reaction of Ti₂AlN with HCl is Ti₂N—Cl₂, the reaction is carried out at 700° C. and kept for 20 min; the subsequent H₂S treatment results in a target product Ti₂N—S₂ in which the surface functional group is S, and the reaction is carried out at 700° C. and kept for 10 min.

The target product is taken out after the reaction device is naturally cooled to room temperature. The target product obtained after the reaction of Ti₂AlN with hydrogen chloride and hydrogen sulfide is subject to SEM test, and the result is shown in FIG. 55a. The target product after the reaction exhibits an obvious accordion-like layer structure, which has an obvious expansion structure stacked layer-by-layer. The target product with such accordion-like structure is subject to XRD analysis, and the result is shown in FIG. 55b. By comparison, the (002) peak of the target product after reaction with HCl and hydrogen sulfide is shifted to a low angle of 9.8°, indicating that the H₂S treatment doesn't change the crystal structure of the MX material (MXene) with a sheet-like layer structure, and doesn't produce a sulfide sub-phase. Ti₂CTₓ obtained after the reaction of Ti₂AlN with HCl and H₂S is characterized by X-ray photoelectron spectrometer (XPS) for its surface functional group. As shown in FIG. 55c, an obvious signal of S element is detected on the surface of Ti₂NTₓ material, which corresponds to the Ti—S bond on the surface of Ti₂NTₓ. The presence of S element in the nanosheets indicates that the resultant target product is an MX material (Ti₂N—S₂) containing functional group S.

### Embodiment 32

The embodiment takes an example of using Ti₃SiC₂ as the MAX phase material, and using HCl gas as the halogen hydride gas. The fabrication method is similar to that of Embodiment 3, except that the reaction temperature is set at 800° C. and kept for 20 min, and the target product obtained by the reaction of Ti₃SiC₂ with HCl is Ti₃C₂Tₓ.

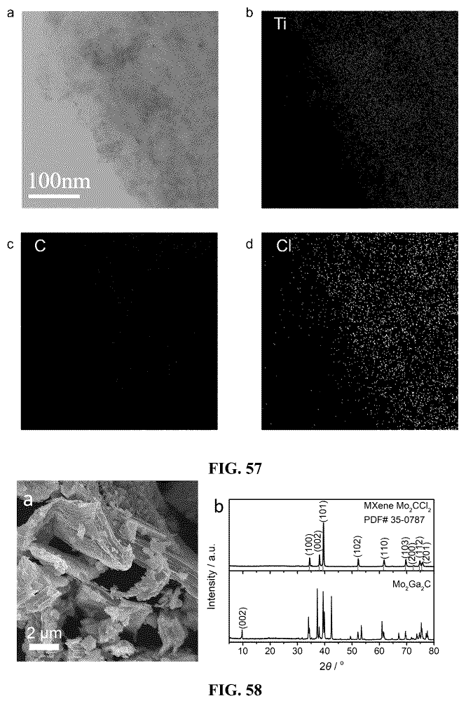

The target product is subject to scanning electron microscope (SEM) test, and the result is shown in FIG. 56a. The target product exhibits an obvious accordion-like layer structure. The MAX phase material Ti₃SiC₂ and the target product are subject to X-ray diffraction (XRD) analysis, and the results are shown in FIG. 56b. By comparison, the (002) peak of the raw material Ti₃SiC₂ appears at 10°, while the (002) peak of the target product obtained after reaction with HCl is shifted to a low angle of 8.6°. It indicates that the HCl gas etches the Al element from Ti₃SiC₂ during the gas phase etching reaction to produce an MX material (MXene) with a sheet-like layer structure and cause the increasing of the layer interval, which is consistent with the result of the SEM photograph of Ti₃C₂Tₓ. The scanning transmission electron microscope (STEM) graph of the transmission electron microscope (TEM) of the target product Ti₃C₂Tₓ is as shown in FIG. 57a, in which the presence of a large amount of two-dimensional ultrathin nanosheets indicates that the accordion-like Ti₃C₂Tₓ can be simply peeled off to obtain two-dimensional nanosheets, the two-dimensional nanosheets have uniform distribution of Ti and C elements (FIG. 57b and FIG. 57c), and the presence of Cl element in the nanosheets (FIG. 57d) indicates that the resultant target product is an MX material (Ti₃C—Cl₂) containing Cl functional group.

### Embodiment 33

The embodiment takes an example of using Mo₂Ga₂C as the MAX phase material, and using HCl gas as the halogen hydride gas. The fabrication method is similar to that of Embodiment 3, except that the reaction temperature is set at 800° C. and kept for 30 min, and the target product obtained by the reaction of Mo₂Ga₂C with HCl is Mo₂CTₓ.

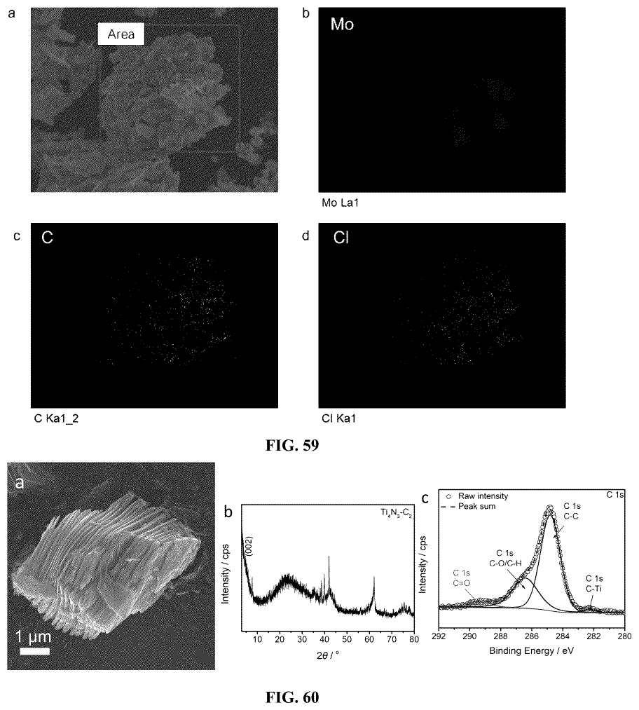

The target product is subject to scanning electron microscope (SEM) test, and the result is shown in FIG. 58a. The target product exhibits an obvious accordion-like layer structure. The MAX phase material Mo₂Ga₂C and the target product are subject to X-ray diffraction (XRD) analysis, and the results are shown in FIG. 58b. By comparison, the (002) peak of the raw material Mo₂Ga₂C appears at 9.6°, while the target product obtained after reaction with HCl exhibits a characteristic peak corresponding to Mo₂C. It indicates that the HCl gas etches the Ga element from Mo₂Ga₂C during the gas phase etching reaction to produce an MX material (MXene) with a sheet-like layer structure and cause the increasing of the layer interval, which is consistent with the result of the SEM photograph of Mo₂CTₓ. The X-ray photoelectron spectrum (EDS) graph of the scanning electron microscope (TEM) of the target product Mo₂CTₓ, as shown in FIG. 59d, the presence of homogeneous Cl element in the two-dimensional nanosheets indicates that the resultant target product is an MX material (Mo₂C—Cl₂) containing Cl functional group.

### Embodiment 34

The embodiment takes an example of using Ti₄AlN₃ as the MAX phase material, using HCl gas as the halogen hydride gas, and using CH₄ gas as the second reaction gas for surface functional-group adjustment. The fabrication method is similar to that of Embodiment 13, except that the target product obtained by the reaction of Ti₄AlN₃ with HCl is Ti₄N₃—Cl₂, the reaction is carried out at 650° C. and kept for 30 min; the subsequent CH₄ treatment results in a target product Ti₄N₃-C₂ in which the surface functional group is C, and the reaction is carried out at 650° C. and kept for 10 min.

After the reaction device is naturally cooled to room temperature, the target product is taken out and subject to SEM analysis. As shown in FIG. 60a, the target product has an accordion-like structure, which is consistent with the morphology of the product obtained by the reaction HCl and Ti₄AlN₃. The target product is subject to XRD test, and the result is shown in FIG. 60b. The (002) peak of the target product is shifted to a low angle of 4.8°, corresponding to the (002) peak of the MXene Ti₄N₃, indicating that the CH₄ treatment neither changes the crystal structure of the MX material (MXene) with a sheet-like layer structure, nor produces a sub-phase. The surface functional group of Ti₄N₃Tₓ obtained by the reaction of Ti₄AlN₃ with HCl is characterized by X-ray photoelectron spectrometer (XPS). As shown in FIG. 60c, an obvious signal of Cl—Ti bond is detected on the surface of the Ti₄N₃Tₓ material, which corresponds to the C functional group on the surface of Ti₄N₃Tₓ. The presence of C element in the nanosheets indicates that the resultant target product is an MX material (Ti₄N₃-C₂) containing C functional group.

The above embodiments are some exemplarily implementations provided for illustrating the technical features of the present disclosure, and the present disclosure is not limited hereto. Many variations or modifications can be made without departing from the inventive concept of the present disclosure. The protection scope of the present disclosure depends on the accompanying claims.

### INDUSTRIAL APPLICABILITY

The present disclosure produces MXenes by etching MAX materials by using a gas phase method, which avoids the steps of repeated washing, ultrasonication, centrifugal separation, drying, etc., during the fabrication of MXenes by using a liquid phase method, thereby greatly simplifying the production process, reducing the production cost, and realizing a large-scale industrial production of MXenes. Thus, the present disclosure possesses industrial applicability.

1. A method for fabricating a two-dimensional material by using gas phase method, the method comprising:
a gas phase etching step, wherein a gas having an etching effect reacts with a MAX phase material at a first predetermined temperature to etch an A component from the MAX phase material, and a two-dimensional material containing MX is obtained, wherein the gas having the etching effect comprises at least one selected from the group of a halogen elementary substance, a halogen hydride, and a nitrogen-family hydride,
wherein the halogen elementary substance is Br₂; the halogen hydride is HCl, HBr or HI; and
the nitrogen-family hydride is NH₃ or H₃P.

2. (canceled)

3. (canceled)

4. The method for fabricating the two-dimensional material by using gas phase method according to claim 1, wherein the first predetermined temperature is from 500° C. to 1200° C.

5. The method for fabricating the two-dimensional material by using gas phase method according to claim 1, wherein the gas in the gas phase etching step further comprises a carrier gas, the carrier gas at least one selected from the group of helium gas, neon gas, argon gas, krypton gas, xenon gas, and nitrogen gas.

6. The method for fabricating the two-dimensional material by using gas phase method according to claim 1, wherein:
the gas having the etching effect is produced by thermal decomposition or sublimation of a solid, or by gasification of a liquid; or
the gas having the etching effect is produced by a chemical reaction of a compound with an acid solution.

7. The method for fabricating the two-dimensional material by using gas phase method according to claim 6, wherein the solid is a halogen ammonium compound or an iodine elementary substance; the liquid is a halogen acid solution; and the compound is a halogen metal salt.

8. The method for fabricating the two-dimensional material by using gas phase method according to claim 1,
wherein the method further comprises:
an adjustment step, wherein the two-dimensional material containing MX reacts with a functional gas at a second predetermined temperature, the functional gas is an elemental substance or a hydride of the fourth, fifth, or sixth main groups,
wherein the adjustment step results in a two-dimensional material containing an element of the fourth, fifth, or sixth main groups.

9. The method for fabricating the two-dimensional material by using gas phase method according to claim 8, wherein the elemental substance of the fourth main group is C, Si or Ge; the hydride of the fourth main group is CH₄, C₂H₈, C₂H₄, H₄Ge or H₄Si; the elemental substance of the fifth main group is P; the hydride of the fifth main group is NH₃ or PH₃; the elemental substance of the sixth main group is O₂, S, Se or Te; and the hydride of the sixth main group is H₂S, H₂Se or H₂Te.

10. The method for fabricating the two-dimensional material by using gas phase method according to claim 8, wherein the element of the fourth, fifth, or sixth main groups replaces part or all of functional groups of the two-dimensional material containing MX to obtain a two-dimensional material containing a functional group of the element of the fourth, fifth, or sixth main groups.

11. The method for fabricating the two-dimensional material by using gas phase method according to claim 9, wherein the second predetermined temperature is from 100° C. and 600° C.

12. The method for fabricating the two-dimensional material by using gas phase method according to claim 8, wherein the element of the fourth, fifth, or sixth main groups replaces part or all of X component in the two-dimensional material containing MX, and the adjustment step results in a two-dimensional material containing the element of the fourth, fifth, or sixth main groups.

13. The method for fabricating the two-dimensional material by using gas phase method according to claim 9, wherein the second predetermined temperature is from 600° C. and 1500° C.

14. The method for fabricating the two-dimensional material by using gas phase method according to claim 1,
wherein a functional gas is provided in the gas phase etching step, the functional gas is an elemental substance or a hydride of the fourth, fifth, or sixth main groups, so that the MAX phase material undergoes a gas phase etching reaction with the gas having the etching effect and simultaneously the two-dimensional material containing MX and the functional gas undergo a functional-group adjustment reaction and/or a conversion reaction,
wherein the gas phase etching step results in a two-dimensional material containing an element of the fourth, fifth, or sixth main groups.

15. The method for fabricating the two-dimensional material by using gas phase method according to claim 14, wherein the elemental substance of the fourth main group is C, Si or Ge; the hydride of the fourth main group is CH₄, C₂H₈, C₂H₄, H₄Ge or H₄Si; the elemental substance of the fifth main group is P; the hydride of the fifth main group is NH₃ or PH₃; the elemental substance of the sixth main group is O₂, S, Se or Te; and the hydride of the sixth main group is H₂S, H₂Se or H₂Te.

16. The method for fabricating the two-dimensional material by using gas phase method according to claim 1, wherein in the MAX phase material, M represents a transition metal element; A represents a main group element and/or transition metal element; and X represents at least one selected from the group of carbon, nitrogen, and boron.

17. A system for fabricating a two-dimensional material by using gas phase method, comprising:
a reaction device, having a temperature-controllable reaction chamber configured for a reaction of a gas having an etching effect with a MAX phase material at a predetermined temperature to obtain a two-dimensional material containing MX; and
a first gas device, configured for introducing the gas having the etching effect into the reaction device.

18. The system for fabricating the two-dimensional material by using gas phase method according to claim 17, wherein the first gas device is a gas-production device configured for producing the gas having the etching effect by thermal decomposition or sublimation of a solid; or by gasification of a liquid; or by a chemical reaction of a compound with an acid solution.

19. The system for fabricating the two-dimensional material by using gas phase method according to claim 17, wherein the first gas device is provided in the reaction chamber.

20. The system for fabricating the two-dimensional material by using gas phase method according to claim 17, further comprising:
an exhaust-gas absorption device, configured for absorbing unreacted portion of the gas having the etching effect in the reaction device; and/or
an exhaust-gas recovery device, configured for storing unreacted gas or re-introducing the unreacted gas into the reaction device.

21. The system for fabricating the two-dimensional material by using gas phase method according to claim 17, further comprising:
a second gas device, configured for introducing a second gas into the reaction device to participate in the reaction.

22. A use of a two-dimensional material fabricated by the method for fabricating the two-dimensional material by using gas phase method according to claim 1 in supercapacitors, metal batteries, catalyzation, electromagnetic shielding, wave-absorbing coatings, electronic devices, or as superconducting material.
